(19) United States
(12) Patent Application Publication
(10) Pub. No.: US 2026/0317161 A1
(43) Pub. Date: Oct. 15, 2026

(54) SENSING DEVICE

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Wei Chen, Beijing (CN); Hanqing Liu, Beijing (CN); Zhiyong Wang, Beijing (CN); Xiaoke Tan, Beijing (CN); Jing Xue, Beijing (CN); Yanyan Yin, Beijing (CN); Qi Sun, Beijing (CN); Xi Yang, Beijing (CN); Xin Li, Beijing (CN); Chuncheng Che, Beijing (CN); Mingjing Liu, Beijing (CN)

(73) Assignees: BEIJING BOE OPTOELECTRONICS TECHNOLOGY CO., LTD., Beijing (CN); BOE TECHNOLOGY GROUP CO., LTD., Beijing (CN)

(21) Appl. No.: 18/995,641

(22) PCT Filed: Nov. 17, 2023
(86) PCT No.: PCT/CN2023/132354

§ 371 Date: Jan. 16, 2025

(51) Int. Cl. B81B 7/02

(52) U.S. Cl. CPC B81B 7/02; B81B 2201/0235; B81B 2201/0264; B81B 2201/0278; B81B 2203/0315; B81B 2203/04; B81B 2207/07

(57) ABSTRACT

The present disclosure provides a sensing device. The sensing device includes two sensors, a first sensor includes a first cavity, a first electrode layer and a plurality of first thermal deformation structures, wherein the first electrode layer is arranged on a side of the first cavity away from an isolation layer, and the plurality of first thermal deformation structures are arranged in the first cavity and are in contact with two inner walls opposite to the first cavity; and a second sensor includes a second cavity, a second electrode layer and a plurality of second thermal deformation structures, wherein the second electrode layer is arranged on a side of the isolation layer away from the first cavity, and the plurality of second thermal deformation structures are arranged in the second cavity and are in contact with two inner walls opposite to the second cavity.

### FIELD

The present disclosure relates to the field of micro-electro mechanical system (MEMS), and more particularly to a sensing device.

### BACKGROUND

Micro-electro mechanical system (MEMS) sensors are a new type of sensor manufactured using microelectronics and micromachining technologies. In the related art, MEMS chips can measure physical quantities such as pressure and acceleration.

However, at present, it is difficult for the MEMS chips to directly measure temperatures, and it is necessary to use external temperature sensors such as temperature sensors with PIN structure to measure the temperatures in combination with the MEMS chips. Since the temperatures respectively on the temperature sensors with PIN structure and the MEMS chips may be uneven, the physical quantities (for example, the pressure, the acceleration, and the like) tested by the MEMS chips do not match temperature values measured by the temperature sensors with PIN structure.

### SUMMARY

Embodiments of the present disclosure adopt the following technical solutions.

In a first aspect, the embodiments of the present disclosure provide a sensing device, including an isolation layer, and a first sensor and a second sensor respectively located on both sides of the isolation layer, wherein an orthographic projection of the first sensor on the isolation layer overlaps with an orthographic projection of the second sensor on the isolation layer;
the first sensor includes a first cavity, a first electrode layer and a plurality of first thermal deformation structures, wherein the first electrode layer is arranged on a side of the first cavity away from the isolation layer, and the plurality of first thermal deformation structures are arranged in the first cavity and are in contact with two inner walls opposite to the first cavity; and the second sensor includes a second cavity, a second electrode layer and a plurality of
second thermal deformation structures, wherein the second electrode layer is arranged on a side of the isolation layer away from the first cavity, and the plurality of second thermal deformation structures are arranged in the second cavity and are in contact two inner walls opposite to the second cavity.

In at least one sensing device provided by the embodiments of the present disclosure, under the same external air pressure environment, the first electrode layer is configured to generate a first deflection, the second electrode layer is configured to generate a second deflection, and a changing trend of the first deflection and a changing trend of the second deflection are opposite.

In at least one sensing device provided by the embodiments of the present disclosure, the first cavity includes a first closed sub-cavity, and the second cavity includes a second closed sub-cavity and a first open sub-cavity, wherein the first open sub-cavity is located on a side of the second closed sub-cavity away from the isolation layer; and

the plurality of second thermal deformation structures are arranged in the first open sub-cavity and are in contact with two inner walls opposite to the first open sub-cavity, and the second electrode layer is arranged on a side of the second closed sub-cavity away from the isolation layer.

In at least one sensing device provided by the embodiments of the present disclosure, a volume of a cavity structure in the first closed sub-cavity is approximately equal to a volume of a cavity structure in the second closed sub-cavity.

In at least one sensing device provided by the embodiments of the present disclosure, the second electrode layer is arranged between the second closed sub-cavity and the first open sub-cavity; or

the second electrode layer is arranged on a side of the first open sub-cavity close to the second closed sub-cavity.

In at least one sensing device provided by the embodiments of the present disclosure, the first cavity includes a second open sub-cavity, and the second cavity includes a third open sub-cavity and a fourth open sub-cavity, wherein the third open sub-cavity is arranged on a side of the fourth open sub-cavity away from the isolation layer; and

the plurality of second thermal deformation structures are arranged in the third open sub-cavity and are in contact with two inner walls opposite to the third open sub-cavity, and the second electrode layer is arranged on a side of the third open sub-cavity close to the fourth open sub-cavity and is in contact with the plurality of second thermal deformation structures.

In at least one sensing device provided by the embodiments of the present disclosure, the sensing device further includes a common electrode layer, a first insulating layer and a second insulating layer, wherein the first insulating layer is located on a side of the common electrode layer close to the first cavity, and the second insulating layer is located between the common electrode layer and the isolation layer; and

the common electrode layer is arranged between the first cavity and the second cavity, the first electrode layer and the common electrode layer are respectively used as two electrodes of a first capacitor, and the second electrode layer and the common electrode layer are respectively used as two electrodes of a second capacitor.

In at least one sensing device provided by the embodiments of the present disclosure, the first sensor further includes a first supporting part, a third insulating layer and a fourth insulating layer, wherein the first supporting part is located between the first insulating layer and the third insulating layer and is arranged around the first cavity, the fourth insulating layer covers the first electrode layer, and the plurality of first thermal deformation structures are in direct contact with the first insulating layer and the third insulating layer respectively.

In at least one sensing device provided by the embodiments of the present disclosure, in response to the first cavity including the first closed sub-cavity and the second cavity including the second closed sub-cavity and the first open sub-cavity, the plurality of second thermal deformation structures are arranged in the first open sub-cavity and are in contact with the two inner walls opposite to the first open sub-cavity;
the second sensor further includes a fifth insulating layer, a sixth insulating layer, a seventh insulating layer, a second supporting part and a third supporting part, wherein the second supporting part is arranged between the fifth insulating layer and the sixth insulating layer and is arranged around the second closed sub-cavity, the third supporting part is arranged between the second electrode layer and the seventh insulating layer and is arranged around the first open sub-cavity, and the second electrode layer is arranged in the first open sub-cavity and is located on a side of the sixth insulating layer away from the second closed sub-cavity; and
the plurality of second thermal deformation structures are in direct contact with the second electrode layer and the seventh insulating layer respectively, the seventh insulating layer is provided with a plurality of first through holes, and an orthographic projection of each of the plurality of second thermal deformation structures on the isolation layer and a region surrounded by an orthographic projection of an outer contour of each of the plurality of first through holes on the isolation layer do not overlap with each other.

In at least one sensing device provided by the embodiments of the present disclosure, in response to the first cavity including a second open sub-cavity and the second cavity including the third open sub-cavity and the fourth open sub-cavity, the plurality of second thermal deformation structures are arranged in the third open sub-cavity and are in contact with the two inner walls opposite to the third open sub-cavity;

the second sensor further includes a fifth insulating layer, a sixth insulating layer, a seventh insulating layer, a second supporting part and a third supporting part, wherein the second supporting part is arranged between the fifth insulating layer and the sixth insulating layer and is arranged around the fourth open sub-cavity, the third supporting part is arranged between the second electrode layer and the seventh insulating layer and is arranged around the third open sub-cavity, and the second electrode layer is arranged in the third open sub-cavity and is located on a side of the sixth insulating layer away from the fourth open sub-cavity; and

the plurality of second thermal deformation structures are in direct contact with the second electrode layer and the seventh insulating layer respectively, the seventh insulating layer is provided with a plurality of first through holes, the sixth insulating layer is provided with a plurality of second through holes, and the plurality of second through holes pass through the second electrode layer, and an orthographic projection of each of the plurality of second thermal deformation structures on the isolation layer does not overlap with a region surrounded by an orthographic projection of an outer contour of each of the plurality of first through holes on the isolation layer and a region surrounded by an orthographic projection of an outer contour of each of the plurality of second through holes on the isolation layer.

In at least one sensing device provided by the embodiments of the present disclosure, the first sensor includes a plurality of third through holes, wherein the plurality of third through holes sequentially pass through the fourth insulating layer, the first electrode layer and the third insulating layer, and an orthographic projection of each of the plurality of first thermal deformation structures on the isolation layer and a region surrounded by an orthographic projection of an outer contour of each of the plurality of third through holes on the isolation layer do not overlap with each other.

In at least one sensing device provided by the embodiments of the present disclosure, the first sensor further includes a first detection structure;

the first sensor further includes a first insulating layer, a first supporting part, a third insulating layer and a fourth insulating layer, wherein the first insulating layer is located on a side of the isolation layer close to the first closed sub-cavity, the first supporting part is located between the first insulating layer and the third insulating layer and is arranged around the first closed sub-cavity, the fourth insulating layer covers the first electrode layer, and the plurality of first thermal deformation structures are in direct contact with the first insulating layer and the third insulating layer respectively; and

the first detection structure is located on a side of the first electrode layer away from the first closed sub-cavity, and an orthographic projection of the first detection structure on the isolation layer and an orthographic projection of each of the plurality of first thermal deformation structures on the isolation layer do not overlap with each other.

In at least one sensing device provided by the embodiments of the present disclosure, the second sensor further includes a second detection structure;

the second sensor further includes a fifth insulating layer, a sixth insulating layer, a seventh insulating layer, a second supporting part and a third supporting part, wherein the second supporting part is located between the fifth insulating layer and the sixth insulating layer and is arranged around the second closed sub-cavity, the third supporting part is located between the second electrode layer and the seventh insulating layer and is arranged around the first open sub-cavity, the second electrode layer is arranged in the first open sub-cavity and is located on a side of the sixth insulating layer away from the second closed sub-cavity, and the plurality of second thermal deformation structures are in direct contact with the second electrode layer and the seventh insulating layer respectively; and

the second detection structure is arranged in the first open sub-cavity and is in contact with the second electrode layer, and an orthographic projection of the second detection structure on the isolation layer and an orthographic projection of each of the plurality of second thermal deformation structures on the isolation layer do not overlap with each other.

In at least one sensing device provided by the embodiments of the present disclosure, a second parameter includes pressure.

In at least one sensing device provided by the embodiments of the present disclosure, the first cavity includes a third closed sub-cavity, and the second cavity includes a fourth closed sub-cavity,

wherein the first electrode layer is located on a side of the third closed sub-cavity away from the isolation layer, and the second electrode layer is located on a side of the fourth closed sub-cavity away from the isolation layer.

In at least one sensing device provided by the embodiments of the present disclosure, the first sensor further includes a first insulating layer, a third insulating layer, a fourth insulating layer and a first supporting part, wherein the first insulating layer covers the isolation layer, the first supporting part is located between the first insulating layer and the third insulating layer and is arranged around the third closed sub-cavity, the plurality of first thermal deformation structures are in contact with the first insulating layer and the third insulating layer respectively, and the fourth insulating layer is located on a side of the first electrode layer away from the third insulating layer; and

the second sensor further includes a fifth insulating layer, a sixth insulating layer, a seventh insulating layer and a second supporting part, wherein the isolation layer covers the fifth insulating layer, the second supporting part is located between the fifth insulating layer and the sixth insulating layer and is arranged around the fourth closed sub-cavity, the plurality of second thermal deformation structures are in contact with the fifth insulating layer and the sixth insulating layer respectively, and the second electrode layer is located between the sixth insulating layer and the seventh insulating layer.

In at least one sensing device provided by the embodiments of the present disclosure, the first sensor further includes a first sliding electrode, wherein the first sliding electrode is arranged in the third closed sub-cavity and overlaps with an orthographic projection of the first electrode layer on the isolation layer, and the first sliding electrode is configured to slide in a first direction, wherein the first direction is a direction perpendicular to a plane where the isolation layer is located; and

the second sensor further includes a second sliding electrode, wherein the second sliding electrode is arranged in the fourth closed sub-cavity and overlaps with an orthographic projection of the second electrode layer on the isolation layer, and a sliding direction of the first sliding electrode and a sliding direction of the second sliding electrode are the same.

In at least one sensing device provided by the embodiments of the present disclosure, an orthographic projection of the first sliding electrode on the isolation layer and an orthographic projection of each of the plurality of first thermal deformation structures on the isolation layer do not overlap with each other, and an orthographic projection of the second sliding electrode on the isolation layer and an orthographic projection of each of the plurality of second thermal deformation structures on the isolation layer do not overlap with each other; and

the first sliding electrode and the second sliding electrode each include a mass block and one or more extension electrodes, wherein the mass block is connected to the extension electrodes, orthographic projections of the extension electrodes on the isolation layer overlap with the orthographic projection of the first electrode layer or the second electrode layer on the isolation layer, the mass block of the first sliding electrode is slidably connected to the first supporting part, and the mass block of the second sliding electrode is slidably connected to the second supporting part.

In at least one sensing device provided by the embodiments of the present disclosure, the second cavity further includes a fifth open sub-cavity, wherein the fifth open sub-cavity is located on a side of the fourth closed sub-cavity away from the isolation layer;

the first sensor further includes a first insulating layer, a third insulating layer, a fourth insulating layer and a first supporting part, wherein the first insulating layer covers the isolation layer, the first supporting part is located between the first insulating layer and the third insulating layer and is arranged around the third closed sub-cavity, the plurality of first thermal deformation structures are in contact with the first insulating layer and the third insulating layer respectively, and the fourth insulating layer is located on a side of the first electrode layer away from the third insulating layer; and

the second sensor further includes a fifth insulating layer, a sixth insulating layer, a seventh insulating layer, a second supporting part and a third supporting part, wherein the isolation layer covers the fifth insulating layer, the second supporting part is located between the fifth insulating layer and the sixth insulating layer and is arranged around the fourth closed sub-cavity, the second electrode layer is located in the fifth open sub-cavity and is in contact with the sixth insulating layer, the third supporting part is located between the second electrode layer and the seventh insulating layer and is arranged around the fifth open sub-cavity, and the plurality of second thermal deformation structures are located in the fifth open sub-cavity and are in contact with the second electrode layer and the seventh insulating layer.

In at least one sensing device provided by the embodiments of the present disclosure, the first sensor includes a first sliding electrode, wherein the first sliding electrode is arranged in the third closed sub-cavity and overlaps with an orthographic projection of the first electrode layer on the isolation layer, and the first sliding electrode is configured to slide in a first direction, wherein the first direction is a direction parallel to a plane where the isolation layer is located; and
the second sensor further includes a second sliding electrode, wherein the second sliding electrode is arranged in the fourth closed sub-cavity and overlaps with an orthographic projection of the second electrode layer on the isolation layer, and a sliding direction of the first sliding electrode and a sliding direction of the second sliding electrode are the same.

In at least one sensing device provided by the embodiments of the present disclosure, an orthographic projection of the first sliding electrode on the isolation layer and an orthographic projection of each of the plurality of first thermal deformation structures on the isolation layer do not overlap with each other, and an orthographic projection of the second sliding electrode on the isolation layer and an orthographic projection of each of the plurality of second thermal deformation structures on the isolation layer do not overlap with each other; and

the first sliding electrode and the second sliding electrode each include a mass block and one or more extension electrodes, wherein the mass block is connected to the extension electrodes, orthographic projections of the extension electrodes on the isolation layer overlap with the orthographic projection of the first electrode layer or the second electrode layer on the isolation layer, the mass block of the first sliding electrode is slidably connected to the first insulating layer, the mass block of the second sliding electrode is slidably connected to the sixth insulating layer, the seventh insulating layer is provided with a plurality of first through holes, and an orthographic projection of each of the plurality of second thermal deformation structures on the isolation layer and a region surrounded by an orthographic projection of an outer contour of each of the plurality of first through holes on the isolation layer do not overlap with each other.

In at least one sensing device provided by the embodiments of the present disclosure, the first sliding electrode and the second sliding electrode are the same;

in response to the first direction being the direction perpendicular to the plane where the isolation layer is located, a size of the mass block in the direction perpendicular to the plane where the isolation layer is located is less than a size of a cavity in which the mass block is located in the direction perpendicular to the plane where the isolation layer is located; and

in response to the first direction being the direction parallel to the plane where the isolation layer is located, sizes of the first sliding electrode and the second sliding electrode in the direction parallel to the plane where the isolation layer is located are less than sizes of cavities in which the first sliding electrode and the second sliding electrode are located in the direction parallel to the plane where the isolation layer is located.

In at least one sensing device provided by the embodiments of the present disclosure, the first sensor further includes a third detection structure, wherein the third detection structure is arranged on a side of the first electrode layer away from the third closed sub-cavity, and an orthographic projection of the third detection structure on the isolation layer and an orthographic projection of each of the plurality of first thermal deformation structures on the isolation layer do not overlap with each other; and

the second sensor further includes a fourth detection structure, wherein the fourth detection structure is arranged on a side of the second electrode layer away from the fourth closed sub-cavity, an orthographic projection of the fourth detection structure on the isolation layer and an orthographic projection of each of the plurality of second thermal deformation structures on the isolation layer do not overlap with each other, and the orthographic projection of the third detection structure on the isolation layer overlaps with the orthographic projection of the fourth detection structure on the isolation layer.

In at least one sensing device provided by the embodiments of the present disclosure, a second parameter includes acceleration.

In at least one sensing device provided by the embodiments of the present disclosure, materials and structures of the first plurality of thermal deformation structures and the plurality of second thermal deformation structures are the same.

In at least one sensing device provided by the embodiments of the present disclosure, orthographic projections of the first plurality of thermal deformation structures on the isolation layer overlap with orthographic projections of the plurality of second thermal deformation structures on the isolation layer.

In at least one sensing device provided by the embodiments of the present disclosure, the plurality of first thermal deformation structures and the plurality of second thermal deformation structures each include a plurality of thermal deformation patterns, and a distance between any two adjacent thermal deformation patterns is equal.

In at least one sensing device provided by the embodiments of the present disclosure, the materials of the plurality of first thermal deformation structures and the plurality of second thermal deformation structures include thermoelastic materials.

In at least one sensing device provided by the embodiments of the present disclosure, the second sensor is embedded in a substrate, and the isolation layer covers the substrate.

The above description is only an overview of the technical solutions of the present disclosure. In order to understand technical means of the present disclosure more clearly, it can be implemented according to contents of the specification, and in order to make the above and other purposes, features and advantages of the present disclosure more obvious and understandable, the specific embodiments of the present disclosure are provided below.

### BRIEF DESCRIPTION OF THE DRAWINGS

In order to more clearly explain the technical solutions in the embodiments of the present disclosure or the related art, drawings needed in the description of the embodiments or the related art will be briefly introduced below. Obviously, the drawings described below are only some embodiments of the present disclosure. For a person skilled in the art, other drawings can be obtained according to these drawings without creative work.

FIG. 1 is a schematic structural diagram of a sensing device in the related art provided by an embodiment of the present disclosure.

FIG. 2 to FIG. 9 are schematic structural diagrams of eight sensing devices for simultaneously measuring temperature and pressure provided by embodiments of the present disclosure.

FIG. 10A to FIG. 13 are schematic structural diagrams of six sensing devices for simultaneously measuring temperature and acceleration provided by embodiments of the present disclosure.

FIG. 14 and FIG. 15 are schematic top views of sliding electrodes provided by embodiments of the present disclosure, where the sliding electrodes include a first sliding electrode and a second sliding electrode.

FIG. 16 is a schematic top view of a plurality of thermal deformation structures provided by an embodiment of the present disclosure, where the plurality of thermal deformation structures include a plurality of first thermal deformation structures and a plurality of second thermal deformation structures.

FIG. 17 to FIG. 25 are schematic diagrams of intermediate structures in a manufacturing process of a sensing device provided by embodiments of the present disclosure.

### DETAILED DESCRIPTION

Technical solutions in embodiments of the present disclosure will be clearly and completely described below with reference to the drawings in the embodiments of the present disclosure. Obviously, the described embodiments are only a part of the embodiments of the present disclosure, but not the whole embodiments. Based on the embodiments of the present disclosure, all other embodiments obtained by a person skilled in the art without creative work belong to the protection scope of the present disclosure.

In the embodiments of the present disclosure, words “first”, “second”, “third” and “fourth” are used to distinguish the same or similar items with basically the same functions and effects, only to clearly describe the technical solutions of the embodiments of the present disclosure, and cannot be understood as indicating or implying relative importance or implicitly indicating the number of indicated technical features.

In the embodiments of the present disclosure, terms “up” and “down” indicate the orientation or positional relationship based on the orientation or positional relationship shown in the accompanying drawings, only for the convenience of describing the present disclosure and simplifying the description, and do not indicate or imply that the devices or elements referred to must have a specific orientation, be constructed and operated in a specific orientation, and therefore cannot be understood as limitations on the present disclosure.

In the description of the specification, terms “one embodiment”, “some embodiments”, “exemplary embodiments”, “an example”, “specific examples” or “some examples” are intended to indicate that specific features, structures, materials or characteristics related to the embodiments or examples are included in at least one embodiment or example of the present disclosure. The schematic representations of the above terms do not necessarily refer to the same embodiment or example. In addition, the described specific features, structures, materials or characteristics may be included in any one or more embodiments or examples in any appropriate manner.

In the embodiments of the present disclosure, “a plurality of” means two or more, and “at least one” means one or more, unless otherwise specifically defined.

The features “parallel”, “perpendicular” and “same” used in the embodiments of the present disclosure all include features such as “parallel”, “perpendicular” and “same” in the strict sense, and the conditions such as “approximately parallel”, “approximately perpendicular”, “approximately the same” contain certain tolerances. Considering the measurement and the tolerance related to the measurement of a specific quantity (for example, limitations of measurement systems), the expression is within the acceptable deviation range for a specific value determined by a person skilled in the art. For example, “approximately” can mean within one or more standard deviations, or within 10% or 5% of the stated value.

Unless the context requires otherwise, throughout the specification and claims, the term “including” is interpreted as an open and inclusive meaning, that is, “including but not limited to”.

“Same layer” in the embodiments of the present disclosure refers to the relationship between a plurality of film layers formed of the same material after the same step (for example, one-step patterning process). The “same layer” herein does not always mean that the thickness of the plurality of film layers is the same or the height of the plurality of film layers in cross-sectional view is the same. Polygons in this specification are not strictly defined, but can be approximate triangles, parallelograms, trapezoids, pentagon or hexagons, and the like, and there can be some small deformations caused by tolerances.

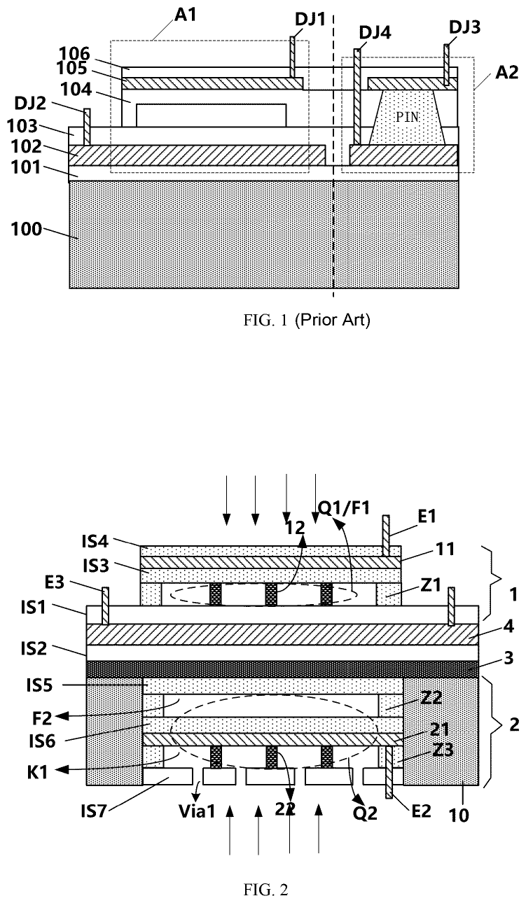

In the related art, micro-electro mechanical system (MEMS) chips can measure physical quantities such as pressure and acceleration. However, at present, it is difficult for the MEMS chips to directly measure temperatures, and it is necessary to use external temperature sensors (for example, temperature sensors with PIN structure shown in FIG. 1) to measure the temperatures in combination with the MEMS chips. Since different positions between external temperature sensors with the MEMS chips (for example, MEMS pressure sensors), the temperatures respectively on the temperature sensors with PIN structure and the MEMS chips may be uneven, the physical quantities (for example, the pressure, the acceleration, and the like) tested by the MEMS chips do not match temperature values measured by the temperature sensors with PIN structure.

FIG. 1 shows a schematic structural diagram of a sensing device in the related art. The sensing device includes a pressure sensor A1 and a temperature sensor A2, where the pressure sensor A1 includes an insulating layer 101, an insulating layer 103, an insulating layer 104 and an insulating layer 106, a first electrode 102, a second electrode 105 and a pressure reference cavity (not marked) located on a substrate 100, where a pressure sensitive film includes a partial region of the insulating layer 104, a partial region of the second electrode 105 and a partial region of the insulating layer 106. When pressure is generated from the outside, the pressure sensitive film is deformed, and the deformation of the pressure sensitive film is approximately proportional to the pressure applied by the outside within a certain range. In general, the pressure sensitive film is provided with a varistor, which is electrically connected to the second electrode 105 and an external electrode (for example, DJ1) respectively, so that a pressure signal is converted into an electrical signal. The temperature sensor A2 includes an electrode DJ3 and an electrode DJ4, and a PIN structure located between the electrode DJ3 and the electrode DJ4. When the temperature changes, current in the PIN structure changes and is transmitted to the outside through the electrodes, and thus a temperature signal is converted into an electrical signal. However, the pressure sensor A1 and the temperature sensor A2 shown in FIG. 1 are arranged at different positions on the substrate 100, and there may be a difference in the temperatures borne by the pressure sensor A1 and the temperature sensor A2 in the external environment. This makes it possible that the pressure measured by the pressure sensor A1 and the temperature measured by the temperature sensor A2 are not values at the same point, and data of the pressure sensor A1 and the temperature sensor A2 do not match.

In addition, MEMS sensors in the related art can include MEMS chips and application specific integrated circuit (ASIC) chips, and the ASIC chips are mainly responsible for precision compensation and correction of the measurement results of the MEMS chips. However, there is a difference between actual compensation points of temperature by the ASIC chips (based on temperature points of the MEMS chip) with actual measurement points of external temperature sensors, resulting in inaccurate compensation by the ASIC chips.

Based on this, embodiments of the present disclosure provide a sensing device. The sensing device is provided with two sensors, a first sensor includes a first cavity, a first electrode layer and a plurality of first thermal deformation structures, the first electrode layer is arranged on a side of the first cavity away from the isolation layer, and the plurality of first thermal deformation structures are arranged in the first cavity and are in contact with two inner walls opposite to the first cavity; the second sensor includes a second cavity, a second electrode layer and a plurality of second thermal deformation structures; the second electrode layer is arranged on a side of the isolation layer away from the first cavity, and the plurality of second thermal deformation structures are arranged in the second cavity and are in contact with two inner walls opposite to the second cavity. In this way, a correlation value of a first parameter can be obtained based on the electrode layers and the cavity (the first cavity or the second cavity) in the two sensors, and a correlation value of a second parameter can be obtained based on a plurality of thermal deformation structures (the plurality of first thermal deformation structures and the plurality of second thermal deformation structures) and the cavity (the first cavity or the second cavity) in the two sensors, and then the first parameter and the second parameter can be calculated based on the correlation value of the first parameter and the correlation value of the second parameter.

In the sensing device provided by the embodiments of the present disclosure, since the electrode, the cavity and the thermal deformation structures are integrated in the same sensor, the same sensor can obtain the correlation value of the first parameter and the correlation value of the second parameter (temperature) at the same time, thereby avoiding the problem that the pressure measured by the pressure sensor A1 and the temperature measured by the temperature sensor A2 in the related art shown in FIG. 1 may not be the values of the same point, and the data of the pressure sensor A1 and the temperature sensor A2 may not match. In addition, the sensing device provided by the embodiments of the present disclosure has high integration, small size, high detection accuracy and wide application.

Exemplary embodiments will now be described more comprehensively with reference to the accompanying drawings.

Embodiments of the present disclosure provide a sensing device. As shown in FIG. 2 to FIG. 13, the sensing device includes an isolation layer 3, and a first sensor 1 and a second sensor 2 respectively located on both sides of the isolation layer 3. An orthographic projection of the first sensor 1 on the isolation layer 3 overlaps with an orthographic projection of the second sensor 2 on the isolation layer 3.

The first sensor 1 includes a first cavity Q1, a first electrode layer 11 and a plurality of first thermal deformation structures 12. The first electrode layer 11 is arranged on a side of the first cavity Q1 away from the isolation layer 3, and the plurality of first thermal deformation structures 12 are arranged in the first cavity Q1 and are in contact with two inner walls opposite to the first cavity Q1.

The second sensor 2 includes a second cavity Q2, a second electrode layer 21 and a plurality of second thermal deformation structures 22. The second electrode layer 21 is arranged on a side of the isolation layer 3 away from the first cavity Q1, and the plurality of second thermal deformation structures 22 are arranged in the second cavity Q2 and are in contact with two inner walls opposite to the second cavity Q2.

The first sensor 1 and the second sensor 2 are configured to be able to jointly measure a first parameter and a second parameter. The first parameter includes environment temperature.

The isolation layer 3 can be used to isolate temperature to avoid temperature interference between the first sensor 1 and the second sensor 2.

In some embodiments, one of the first sensor 1 and the second sensor 2 can be embedded in a substrate 10. For example, the second sensor 2 can be embedded in the substrate 10.

Materials of the substrate 10 in the above sensing device are not limited here. For example, the materials of the substrate 10 can be inorganic materials such as one of glass, silicon nitride, silicon oxide, silicon oxynitride and silicon material; or, the materials of the substrate 10 can be organic materials with a certain mechanical strength such as resin and engineering plastic.

The silicon material can include monocrystalline silicon, polycrystalline silicon, amorphous silicon and doped silicon.

For example, the materials of the substrate 10 can be N-type silicon, or the materials of the substrate can be P-type silicon.

For example, when the materials of the substrate 10 include the silicon material, the isolation layer 3 can also be used to isolate carriers in the substrate 10 to avoid signal crosstalk caused by carrier migration on both sides of the isolation layer 3.

For example, materials of the isolation layer 3 can be insulating materials such as organic insulating materials or inorganic insulating materials.

The first cavity Q1 and the second cavity Q2 are both cavity structures. The first cavity Q1 (the second cavity Q2) can be in a vacuum state; or, the first cavity Q1 (the second cavity Q2) can be filled with gas. The specific type of the gas filled in the cavity structure is not limited here, and can be determined according to actual situations.

For example, the vacuum state of the first cavity Q1 and the vacuum state of the second cavity Q2 mentioned above are not necessarily the same.

In an exemplary embodiment, an area of an orthographic projection of the first electrode layer 11 on the isolation layer 3 and an area of an orthographic projection of the second electrode layer 21 on the isolation layer 3 are the same, and a thicknesses of the first electrode layer 11 and a thicknesses of the second electrode layer 21 are approximately the same.

In an exemplary embodiment, an area of orthographic projections of the plurality of first thermal deformation structures 12 on the isolation layer 3 and an area of orthographic projections of the plurality of second thermal deformation structures 22 on the isolation layer 3 are the same, and a height of the plurality of first thermal deformation structures 12 and a height of the plurality of second thermal deformation structures 22 in a direction perpendicular to a plane where the isolation layer 3 is located are approximately the same.

In an exemplary embodiment, the second parameter can include pressure (relative pressure and absolute pressure) or acceleration.

For example, the first sensor 1 and the second sensor 2 are configured to be able to jointly measure pressure and temperature. The pressure can include air pressure.

As another example, the first sensor 1 and the second sensor 2 are configured to be able to jointly measure acceleration and temperature.

In an exemplary embodiment, the orthographic projections of the plurality of first thermal deformation structures 12 on the isolation layer 3 overlap with the orthographic projections of the plurality of second thermal deformation structure 22 on the isolation layer 3.

The shapes and sizes of the orthographic projections of the plurality of first thermal deformation structures 12 on the isolation layer 3 and the shapes and sizes of the orthographic projections of the plurality of second thermal deformation structures 22 on the isolation layer 3 are the same.

The shapes of the orthographic projections of the plurality of first thermal deformation structures 12 and the plurality of second thermal deformation structures 22 on the isolation layer 3 are not limited here. For example, the shapes of the orthographic projections of the plurality of first thermal deformation structures 12 and the plurality of second thermal deformation structures 22 on the isolation layer 3 can both be polygons such as quadrangles and pentagons; or, the shapes of the orthographic projections of the plurality of first thermal deformation structures 12 and the plurality of second thermal deformation structures 22 on the isolation layer 3 can be both arc-shaped such as circular or elliptical; or, the shape of the orthographic projection of the plurality of first thermal deformation structures 12 and the plurality of second thermal deformation structures 22 on the isolation layer 3 can be a combination of polygons and arcs. The combination of polygons and arcs refers to an image formed by splicing polygons and arcs or a shape formed by removing local regions from polygons and arcs.

In an exemplary embodiment, the plurality of first thermal deformation structures 12 and the plurality of second thermal deformation structures 22 can each include a plurality of thermal deformation patterns, and the plurality of thermal deformation patterns are distributed in the cavity structure and are in contact with two opposite inner walls in the cavity structure where the plurality of thermal deformation patterns are located. The plurality of thermal deformation patterns refers to two or more thermal deformation patterns refers.

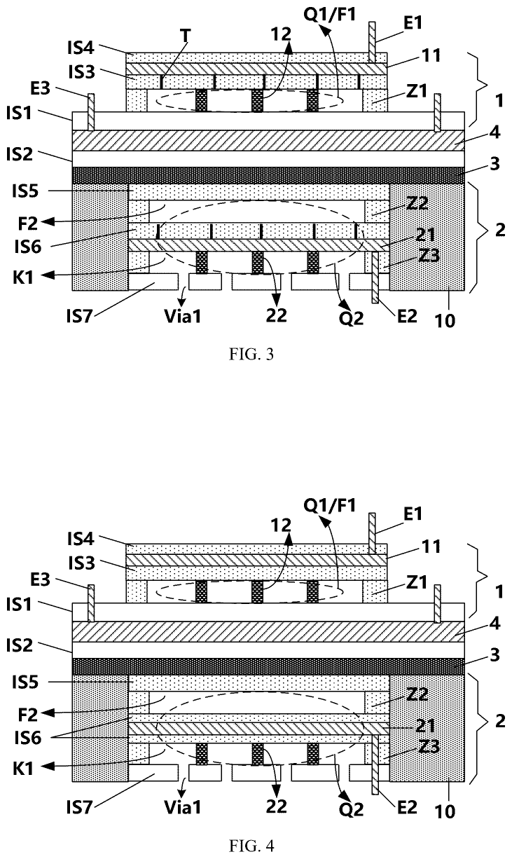

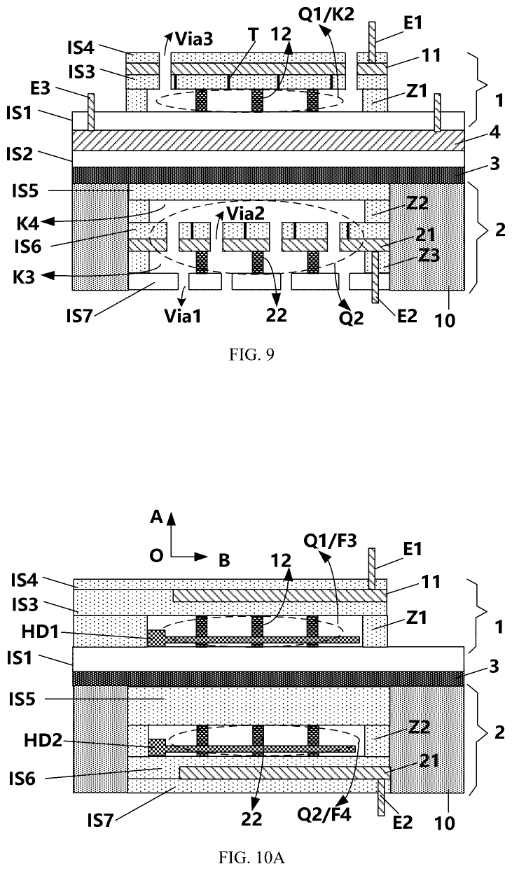

In practical applications, the plurality of first thermal deformation structures 12 and the plurality of second thermal deformation structures 22 can undergo thermal deformation (or thermal expansion) under the condition of temperature rise, so that the height of the plurality of first thermal deformation structures 12 and the height of the plurality of second thermal deformation structures 22 increase in the direction perpendicular to the plane where the isolation layer 3 is located. For sensing devices such as those shown in FIG. 2, FIG. 3, FIG. 4, FIG. 8, FIG. 9, FIG. 10A and FIG. 10B, since the first electrode layer 11 serves as one electrode of a capacitor structure (the other electrode of the capacitor will be described later) and the second electrode layer 21 serves as one electrode of another capacitor structure (the other electrode of the capacitor will be described later), the height of the plurality of first thermal deformation structures 12 and the height of the plurality of second thermal deformation structures 22 increase in the direction perpendicular to the plane where the isolation layer 3 is located, which will change a distance between two electrodes of the capacitor, thereby changing a capacitance value of the capacitor. Based on an amount of change in capacitance value, an amount of change in temperature can be calculated, and thus the temperature detection can be realized based on the plurality of first thermal deformation structures 12 and the plurality of second thermal deformation structures 22. It should be noted that only functions of the plurality of first thermal deformation structures 12 and the plurality of second thermal deformation structures 22 for measuring the temperature are briefly described here, and specific working principles of the sensing devices such as those shown in FIG. 2, FIG. 3, FIG. 4, FIG. 8, FIG. 9, FIG. 10A and FIG. 10B will be described below in combination with specific structures of the sensing devices.

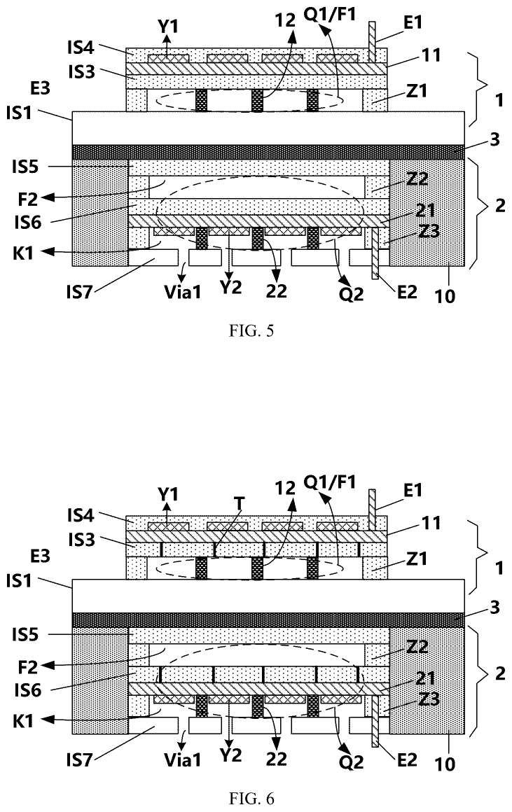

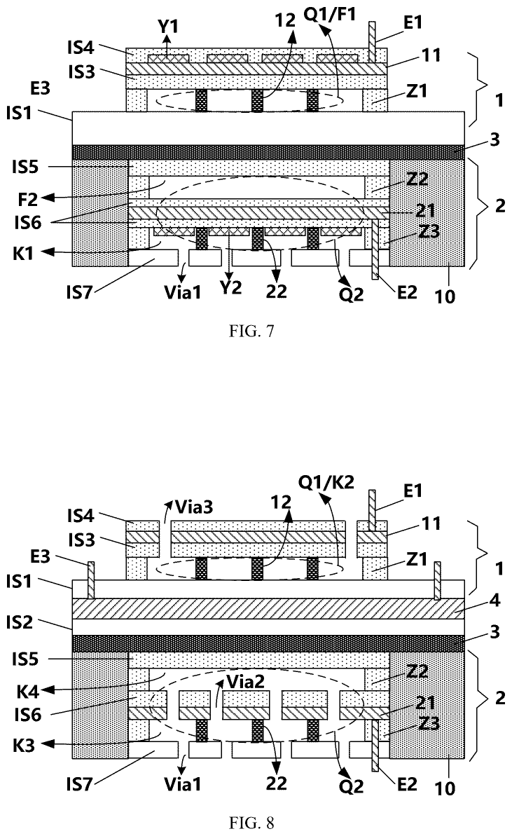

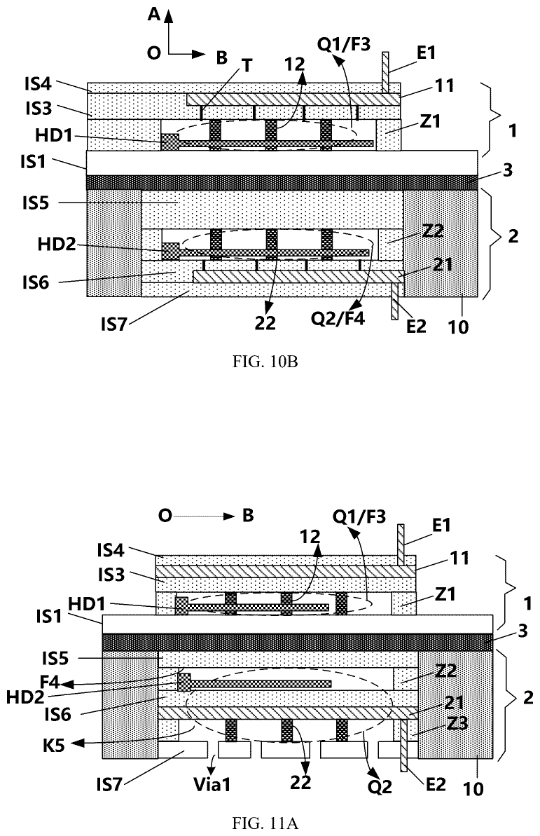

In addition, for sensing devices such as those shown in FIG. 5, FIG. 6, FIG. 7, FIG. 12 and FIG. 13, since the first electrode layer 11 is provided with a detection structure, and the second electrode layer 21 is provided with another detection structure. Materials of the detection structures include piezoelectric materials or piezoresistive materials. Under the condition that the temperatures of the plurality of first thermal deformation structures 12 and the plurality of second thermal deformation structures 22 rise, the height of the plurality of first thermal deformation structures 12 and the height of the plurality of second thermal deformation structures 22 increase in the direction perpendicular to the plane where the isolation layer 3 is located, so that the detection structures are deformed under the action of pressure, and the deformation makes the detection structures change in current. Based on an amount of change in current, the amount of change in temperature can be calculated, and thus the temperature detection can be realized based on the plurality of first thermal deformation structures 12 and the plurality of second thermal deformation structures 22. It should be noted that only functions of the plurality of first thermal deformation structures 12 and the plurality of second thermal deformation structures 22 for measuring temperature are briefly described here, and specific working principles of the sensing devices shown in FIG. 5, FIG. 6, FIG. 7, FIG. 12 and FIG. 13 will be described below in combination with specific structures of the sensing devices.

In the sensing device provided by the embodiments of the present disclosure, a correlation value of a first parameter can be obtained based on the electrode layers and the cavity (the first cavity or the second cavity) in the two sensors, and a correlation value of a second parameter can be obtained based on a plurality of thermal deformation structures (the plurality of first thermal deformation structures 12 and the plurality of second thermal deformation structures 22) and the cavity (the first cavity or the second cavity) in the two sensors, and then the first parameter and the second parameter can be calculated based on the correlation value of the first parameter and the correlation value of the second parameter.

Since the electrode, the cavity and the thermal deformation structures are integrated in the same sensor, the same sensor can obtain the correlation value of the first parameter and the correlation value of the second parameter (temperature) at the same time, thereby avoiding the problem that the pressure measured by the pressure sensor A1 and the temperature measured by the temperature sensor A2 in the related art shown in FIG. 1 may not be the values of the same point, and the data of the pressure sensor A1 and the temperature sensor A2 may not match. In addition, the sensing device provided by the embodiments of the present disclosure has high integration, small size, high detection accuracy and wide application.

In at least one sensing device provided by the embodiments of the present disclosure, for the sensing devices shown in FIG. 2 to FIG. 9, under the same external air pressure environment, the first electrode layer 11 generates a first deflection, the second electrode layer 21 generates a second deflection, and a changing trend of the first deflection and a changing trend of the second deflection are opposite.

In an exemplary embodiment, as shown in FIG. 2, for example, three film layers on an upper side of the first cavity Q1 in the first sensor 1 jointly form a first vibrating film, and the second electrode layer 21 in the second sensor 2 and a sixth insulating layer IS6 in direct contact with the second electrode layer 21 jointly form a second vibrating film. During the testing of the sensing device, both the first vibrating film and the second vibrating film are deformed.

In exemplary embodiments, the sensing devices shown in FIG. 2 to FIG. 9 are sensing devices for measuring temperature and pressure (air pressure). When external pressure is applied, taking an arrow direction marked in FIG. 2 as an example, where the arrow direction refers to a force direction of the first vibrating film and the second vibrating film under the action of air pressure. Under the action of external air pressure, for the first sensor 1 on an upper side of the isolation layer 3, the first vibrating film of the first sensor 1 is deformed in a vertical downward direction; for the second sensor 2 on the upper side of the isolation layer 3, the second vibrating film of the second sensor 2 is deformed in a vertical upward direction. At this time, both the first electrode layer 11 and the second electrode layer 21 have deflection changes in the direction perpendicular to the plane where the isolation layer 3 is located. Specifically, the first electrode layer 11 has deflection changes in the vertical downward direction, while the second electrode layer 21 has deflection changes in the vertical upward direction. The deflection directions of the first electrode layer 11 and the second electrode layer 21 under the action of external air pressure are opposite.

The deflection refers to a linear displacement of an axis of a rod in a direction perpendicular to the axis or a middle plane of a plate shell in a direction perpendicular to the middle plane when the force is applied. Here, the deflection refers to the linear displacement of both the first electrode layer 11 and the second electrode layer 21 in the direction perpendicular to the plane where the isolation layer 3 is located. Generally speaking, the first electrode layer 11 is deformed in the vertical downward direction, and the second electrode layer 21 is deformed in the vertical upward direction.

In at least one sensing device provided by the embodiments of the present disclosure, as shown in FIG. 2, FIG. 3, FIG. 4, FIG. 5, FIG. 6 and FIG. 7, the first cavity Q1 includes a first closed sub-cavity F1, and the second cavity Q2 includes a second closed sub-cavity F2 and a first open sub-cavity K1. The first open sub-cavity K1 is located on a side of the second closed sub-cavity F2 away from the isolation layer 3.

The plurality of second thermal deformation structures 22 are arranged in the first open sub-cavity K1 and are in contact with two inner walls opposite to the first open sub-cavity K1, and the second electrode layer 21 is arranged on a side of the second closed sub-cavity F2 away from the isolation layer 3.

In an exemplary embodiment, an open sub-cavity refers to a cavity structure in an open state, and a closed sub-cavity refers to a cavity structure in a closed state. The open sub-cavity can communicate with external atmospheric pressure, and the closed sub-cavity can be in a vacuum state or a gas-filled state.

It should be noted that for the sensing devices shown in FIG. 2 to FIG. 7, a size and a state of the first closed sub-cavity F1 and a size and a state of the second closed sub-cavity F2 are the same.

For example, the first closed sub-cavity F1 and the second closed sub-cavity F2 are both in the vacuum state or the gas-filled state.

For another example, a volume of the cavity structure in the first closed sub-cavity F1 is approximately equal to a volume of the cavity structure in the second closed sub-cavity F2. Specifically, since the plurality of first thermal deformation structures 12 are arranged in the first closed sub-cavity F1, a space except the plurality of first thermal deformation structures 12 in the first closed sub-cavity F1 is a cavity structure, and a volume of the space except the plurality of first thermal deformation structures 12 in the first closed sub-cavity F1 is approximately the same as a volume of the cavity structure in the second closed sub-cavity F2. At this time, an area of a region surrounded by an orthographic projection of an outer contour of the first closed sub-cavity F1 on the isolation layer 3 can be greater than an area of a region surrounded by an orthographic projection of an outer contour of the second closed sub-cavity F2 on the isolation layer 3.

When the first cavity Q1 includes the first closed sub-cavity F1, and the second cavity

Q2 includes the second closed sub-cavity F2 and the first open sub-cavity K1, an effective reference cavity in the first sensor 1 is the first closed sub-cavity F1 and an effective reference cavity in the second sensor 2 is the second closed sub-cavity F2. Therefore, in order to improve the measurement accuracy, a film structure around the first closed sub-cavity F1 and a film structure around the second closed sub-cavity F2 should be arranged symmetrically as much as possible.

In at least one sensing device provided by the embodiments of the present disclosure, as shown in FIG. 4 and FIG. 7, the second electrode layer 21 is arranged between the second closed sub-cavity F2 and the first open sub-cavity K1.

Alternatively, as shown in FIG. 2, FIG. 3, FIG. 5 and FIG. 6, the second electrode layer 21 is arranged in the first open sub-cavity K1 on a side close to the second closed sub-cavity F2.

In practical applications, as shown in FIG. 4 and FIG. 7, the second electrode layer 21 can be arranged between the second closed sub-cavity F2 and the first open sub-cavity K1, so that a structure of a film layer bearing pressure on an upper side of the first closed sub-cavity F1 and a structure of a film layer bearing pressure on a lower side of the second closed sub-cavity F2 are as symmetrical as possible, and thus the measurement error between the first sensor 1 and the second sensor 2 in the sensing device can be further reduced and the measurement accuracy of the sensing device can be improved.

It should be noted that when the volume of the space except the plurality of first thermal deformation structures 12 in the first closed sub-cavity F1 and the volume of the cavity structure in the second closed sub-cavity F2 are approximately the same, the difference in detection accuracy between the sensing structures shown in FIG. 4 and FIG. 7 with the sensing structures shown in FIG. 2, FIG. 3, FIG. 5 and FIG. 6 can be almost negligible.

In at least one sensing device provided by the embodiments of the present disclosure, as shown in FIG. 8 and FIG. 9, the first cavity Q1 includes a second open sub-cavity K2, and the second cavity Q2 includes a third open sub-cavity K3 and a fourth open sub-cavity K4. The third open sub-cavity K3 is arranged on a side of the fourth open sub-cavity K4 away from the isolation layer 3.

The plurality of second thermal deformation structures 22 are arranged in the third open sub-cavity K3 and are in contact with two inner walls opposite to the third open sub-cavity K3, and the second electrode layer 21 is arranged on a side of the third open sub-cavity K3 close to the fourth open sub-cavity K4 and is in contact with the plurality of second thermal deformation structures 22.

In an exemplary embodiment, the volume of the cavity structure in the second open sub-cavity K2 and the volume of the cavity structure in the fourth open sub-cavity K4 are approximately the same. The cavity structure in the second open sub-cavity K2 refers to a space in the second open sub-cavity K2 except the plurality of first thermal deformation structures 12.

For the sensing devices shown in FIG. 8 and FIG. 9, all three sub-cavities communicate with the external atmospheric pressure, and the sensing devices can be used to detect changes of absolute pressures of the sensing devices caused by external acoustic waves, so as to obtain a frequency range of the acoustic waves according to the changes of the absolute pressures.

In at least one sensing device provided by the embodiments of the present disclosure, as shown in FIG. 2, FIG. 3, FIG. 4, FIG. 8 and FIG. 9, the sensing device further includes a common electrode layer 4, a first insulating layer IS1 and a second insulating layer IS2. The first insulating layer IS1 is located on a side of the common electrode layer 4 close to the first cavity Q1, and the second insulating layer IS2 is located between the common electrode layer 4 and the isolation layer 3.

The common electrode layer 4 is arranged between the first cavity Q1 and the second cavity Q2, the first electrode layer 11 and the common electrode layer 4 are respectively used as two electrodes of a first capacitor, and the second electrode layer 21 and the common electrode layer 4 are respectively used as two electrodes of a second capacitor.

The film layer and the cavity between the first electrode layer 11 and the common electrode layer 4 jointly serve as the insulating medium of the first capacitor, and the film layer and the cavity between the second electrode layer 21 and the common electrode layer 4 jointly serve as the insulating medium of the second capacitor.

In an exemplary embodiment, materials of the common electrode layer 4, the first electrode layer 11 and the second electrode layer 21 can include metals or metal oxides.

For example, the materials of the common electrode layer 4, the first electrode layer 11 and the second electrode layer 21 are the same.

In an exemplary embodiment, materials of the first insulating layer IS1 and the second insulating layer IS2 can include inorganic insulating materials or organic insulating materials. The inorganic insulating materials can include at least one of silicon nitride, silicon oxide or silicon oxynitride, and the organic insulating materials can include resin.

In practical applications, when the temperature rises, the height of the plurality of first thermal deformation structures 12 and the height of the plurality of second thermal deformation structures 22 increase in the direction perpendicular to the plane where the isolation layer 3 is located, that is, the plurality of first thermal deformation structures 12 support the deformation of the first electrode layer 11 in a direction away from the common electrode layer 4, and the plurality of second thermal deformation structures 22 support the deformation of the second electrode layer 21 in a direction close to the common electrode layer 4, so that a distance between the two electrodes of the first capacitor increases, and a distance between the two electrodes of the second capacitor decreases. According to the calculation formula of the capacitor C−εs/4πkd, where C is the capacitance value, ε is a dielectric constant, s is an opposite area between the two electrodes, k is a constant, and d is the distance between the two electrodes, C₁ₜ increases (that is, +C₁ₜ) and C₂ₜ decreases (that is, −C₂ₜ). Cit represents a change of the capacitance value of the first capacitor caused by temperature rise, and C₂ₜ represents a change of the capacitance value of the second capacitor caused by temperature rise.

In at least one sensing device provided by the embodiments of the present disclosure, as shown in FIG. 2, FIG. 3, FIG. 4, FIG. 8 and FIG. 9, the first sensor A1 further includes a first supporting part Z1, a third insulating layer IS3 and a fourth insulating layer IS4. The first supporting part Z1 is located between the first insulating layer IS1 and the third insulating layer IS3 and is arranged around the first cavity Q1, the fourth insulating layer IS4 covers the first electrode layer 11, and the plurality of first thermal deformation structures 12 are in direct contact with the first insulating layer IS1 and the third insulating layer IS3 respectively.

In some embodiments, the first supporting part Z1 and the third insulating layer IS3 can be an integrated structure. The integrated structure refers to being prepared and formed by using the same raw materials in the same process steps. The meaning of similar descriptions in the following is the same as here, and will not be repeated.

In some embodiments, the first supporting part Z1, the first insulating layer IS1 and the third insulating layer IS3 can be an integrated structure.

In an exemplary embodiment, materials of the third insulating layer IS3 and the fourth insulating layer IS4 can include inorganic insulating materials or organic insulating materials. The inorganic insulating materials can include at least one of silicon nitride, silicon oxide or silicon oxynitride, and the organic insulating materials can include resin.

In an exemplary embodiment, the materials of the first insulating layer IS1, the second insulating layer IS2, the third insulating layer IS3 and the fourth insulating layer IS4 are the same.

In exemplary embodiments, as shown in FIG. 3 and FIG. 9, the third insulating layer IS3 is provided with a plurality of etching holes T. In the process of preparing the sensing device, etching liquid is injected through the etching holes T to form a cavity structure. Structures marked with T in the drawings provided by the embodiments of the present disclosure are all etching holes, which are hereby explained. After the cavity structure is formed, the etching holes T can be filled in the subsequent film forming process.

For example, the material of the first electrode layer 11 can be used to fill the etching holes T on the third insulating layer IS3. At this time, the etching holes T on the third insulating layer IS3 can be filled while forming the first electrode layer 11.

For example, the etching holes T on the third insulating layer IS3 can be filled with the same material as the material of the third insulating layer IS3, but an additional filling step is required.

The first supporting part Z1 is located between the first insulating layer IS1 and the third insulating layer IS3 and is arranged around the first cavity Q1, which means that the first supporting part Z1, the first insulating layer IS1 and the third insulating layer IS3 serve as outer walls of the first cavity Q1.

The fourth insulating layer IS4 covers the first electrode layer 11 to protect the first electrode layer 11 from corrosion or damage when the first electrode layer 11 is exposed.

In at least one sensing device provided by the embodiments of the present disclosure, as shown in FIG. 2, FIG. 3 and FIG. 4, in response to the first cavity Q1 including the first closed sub-cavity F1 and the second cavity Q2 including the second closed sub-cavity F2 and the first open sub-cavity K1, the plurality of second thermal deformation structures 22 are arranged in the first open sub-cavity K1 and are in contact with the two inner walls opposite to the first open sub-cavity K1.

As shown in FIG. 2, FIG. 3 and FIG. 4, the second sensor 2 further includes a fifth insulating layer IS5, a sixth insulating layer IS6, a seventh insulating layer IS7, a second supporting part Z2 and a third supporting part Z3. The second supporting part Z2 is arranged between the fifth insulating layer IS5 and the sixth insulating layer IS6 and is arranged around the second closed sub-cavity F2, the third supporting part Z3 is arranged between the second electrode layer 21 and the seventh insulating layer IS7 and is arranged around the first open sub-cavity K1, and the second electrode layer 21 is arranged in the first open sub-cavity K1 and is located on a side of the sixth insulating layer IS6 away from the second closed sub-cavity F2; and the plurality of second thermal deformation structures 22 are in direct contact with the second electrode layer 21 and the seventh insulating layer IS7 respectively, the seventh insulating layer IS7 is provided with a plurality of first through holes Via1, and an orthographic projections of each of the plurality of second thermal deformation structures 22 on the isolation layer 3 and a region surrounded by an orthographic projection of an outer contour of each of the plurality of first through holes Via1 on the isolation layer 3 do not overlap with each other.

For example, materials of the fifth insulating layer IS5, the sixth insulating layer IS6 and the seventh insulating layer IS7 can include inorganic insulating materials or organic insulating materials. The inorganic insulating materials can include at least one of silicon nitride, silicon oxide or silicon oxynitride, and the organic insulating materials can include resin.

For example, the second supporting part Z2, the fifth insulating layer IS5 and the sixth insulating layer IS6 can be an integrated structure.

For example, the third supporting part Z3 and the seventh insulating layer IS7 can be an integrated structure.

For example, the materials of the fifth insulating layer IS5, the sixth insulating layer IS6, the seventh insulating layer IS7, the second supporting part Z2 and the third supporting part Z3 may all be the same.

By arranging the plurality of first through holes Via1 on the seventh insulating layer IS7, the first open sub-cavity K1 is communicated with the external environment.

In addition, it should be noted that in FIG. 3, a plurality of etching holes T are drawn on the sixth insulating layer IS6. In the process of preparing the sensing device, etching liquid is injected through the etching holes T to form a cavity structure (for example, the second closed sub-cavity F2). After the cavity structure is formed, the etching holes T can be filled in the subsequent film forming process.

For example, as shown in FIG. 3, the material of the second electrode layer 21 can be used to fill the etching holes T on the sixth insulating layer IS6. At this time, the etching holes T on the sixth insulating layer IS6 can be filled while forming the second electrode layer 21.

For example, as shown in FIG. 2, the etching holes T on the sixth insulating layer IS6 can be filled with the same material as the material of the sixth insulating layer IS6 (the material is the same after filling), but an additional filling step is required.

In practical applications, the sensing device further includes a plurality of connection electrodes for transmitting electrical signals, for example, a connection electrode E1, a connection electrode E2 and connection electrodes E3 shown in FIG. 2. The connection electrode E1 is electrically connected to the first electrode layer 11, the connection electrode E2 is electrically connected to the second electrode layer 21, and the connection electrodes E3 are electrically connected to the common electrode layer 4. In other embodiments, the setting function of the connection electrodes of the sensing device is similar to that here, and will not be repeated.

Taking the structure of the sensing device shown in FIG. 2 or FIG. 3 as an example, the working principle of the sensing device will be explained in detail. The sensing device shown in FIG. 2 or FIG. 3 can be used to detect relative pressure and temperature at the same time, can be used as a pressure sensor, and can be applied to devices such as electronic watches or unmanned aerial vehicles. The specific working principle is as follows.

Taking conditions of heating and pressing as an example, when the temperature rises, the heights (d) of the plurality of first thermal deformation structures 12 and the plurality of second thermal deformation structures 22 increase in the direction perpendicular to the plane where the isolation layer 3 is located, that is, the plurality of first thermal deformation structures 12 support the deformation of the first electrode layer 11 in a direction away from the common electrode layer 4, and the plurality of second thermal deformation structures 22 support the deformation of the second electrode layer 21 in a direction close to the common electrode layer 4, so that a distance d between the two electrodes of the first capacitor increases, and a distance d between the two electrodes of the second capacitor decreases. According to the calculation formula of the capacitor C=εs/4πkd, where C is the capacitance value, ε is a dielectric constant, s is an opposite area between the two electrodes, k is a constant, and d is the distance between the two electrodes, C₁ₜ decreases (that is, −C₁ₜ) and C₂ₜ increases (that is, +C₂ₜ), where C₁ₜ represents a change of the capacitance value of the first capacitor caused by temperature rise, and C₂ₜ represents a change of the capacitance value of the second capacitor caused by temperature rise.

When the pressure increases, under the external pressure as shown in FIG. 2, the first electrode layer 11 is deformed in a direction toward the common electrode layer 4 and the second electrode layer 21 is deformed in a direction toward the common electrode layer 4, so that the distance d between the two electrodes of the first capacitor decreases, and the distance d between the two electrodes of the second capacitor decreases. According to the calculation formula of the capacitor C=εs/4πkd, C₁ₚ increases (that is, +C₁ₚ) and C₂ₚ increases (that is, +C₂ₚ).

According to the above analysis, under the conditions of heating and pressing,

$$an amount of change in capacitance of the first sensor 1 Δ {C}_{1} = {C}_{1 p} - {C}_{1 t} ; \qquad formula ( 1 )$$

$$an amount of change in capacitance of the second sensor 2 Δ {C}_{2} = {C}_{2 p} - {C}_{2 t} ; \qquad formula ( 2 )$$

since the plurality of first thermal deformation structure 12 and the plurality of second thermal deformation structure 22 are the same, C₁ₜ=C₂ₜ=Cₜ; and since the volumes of the cavity structures of the two closed sub-cavities are the same, C₁ₚ=C₂ₚ=Cₚ;
the above formula (1) and formula (2) are added to obtain:

$$Δ {C}_{1} + Δ {C}_{2} = 2 {C}_{p} ; \qquad formula ( 3 )$$

the above formula (1) and formula (2) are subtracted to obtain:

$${ΔC}_{2} - Δ {C}_{1} = 2 {C}_{t} . \qquad formula ( 4 )$$

There is a preset relationship between the amount of change in capacitance AC and an amount of change in current ΔI, and δ is a constant, that is,

$$Δ C = δ * Δ I ; \qquad formula ( 5 )$$

then ΔC₁=δ*ΔI₁, ΔC₂=δ*ΔI₂; ΔI₁ and ΔI₂ can be directly tested by the circuit external to the sensing device, and then specific values of ΔC₁ and ΔC₂ can be calculated. Combined with the above formula (3) and formula (4) and the specific values of ΔC₁ and ΔC₂, specific values of Cₚ and Cₜ can be calculated, where Cₜ can be referred to as the correlation value of the first parameter (temperature) and Cₚ can be referred to as the correlation value of the second parameter (pressure). Then a temperature value is calculated according to a preset relationship between Cₜ and the temperature, and a pressure value is calculated according to a preset relationship between Cₚ and the pressure.

In at least one sensing device provided by the embodiments of the present disclosure, as shown in FIG. 8 and FIG. 9, in response to the first cavity Q1 includes a second open sub-cavity K2 and the second cavity Q2 includes the third open sub-cavity K3 and the fourth open sub-cavity K4, the plurality of second thermal deformation structures 22 are arranged in the third open sub-cavity K3 and are in contact with the two inner walls opposite to the third open sub-cavity K3.

The second sensor 2 further includes a fifth insulating layer IS5, a sixth insulating layer IS6, a seventh insulating layer IS7, a second supporting part Z2 and a third supporting part Z3. The second supporting part Z2 is arranged between the fifth insulating layer IS5 and the sixth insulating layer IS6 and is arranged around the fourth open sub-cavity K4, the third supporting part Z3 is arranged between the second electrode layer 21 and the seventh insulating layer IS7 and is arranged around the third open sub-cavity K3, and the second electrode layer 21 is arranged in the third open sub-cavity K3 and is located on a side of the sixth insulating layer IS6 away from the fourth open sub-cavity K4.

The plurality of second thermal deformation structures 22 are in direct contact with the second electrode layer 21 and the seventh insulating layer IS7 respectively, the seventh insulating layer IS7 is provided with a plurality of first through holes Via1, the sixth insulating layer IS6 is provided with a plurality of second through holes Via2, and the plurality of second through holes Via2 pass through the second electrode layer 21, and an orthographic projection of each of the plurality of second thermal deformation structures 22 on the isolation layer 3 does not overlap with a region surrounded by an orthographic projection of an outer contour of each of the plurality of first through holes Via1 on the isolation layer 3 and a region surrounded by an orthographic projection of an outer contour of each of the plurality of second through holes Via2 on the isolation layer 3.

In addition, as shown in FIG. 8 and FIG. 9, the first sensor 1 includes a plurality of third through holes Via3. The plurality of third through holes Via3 sequentially pass through the fourth insulating layer IS4, the first electrode layer 11 and the third insulating layer IS3, and an orthographic projection of each of the plurality of first thermal deformation structures 12 on the isolation layer 3 and a region surrounded by an orthographic projection of an outer contour of each of the plurality of third through holes Via3 on the isolation layer 3 do not overlap with each other.

In the embodiments of the present disclosure, as shown in FIG. 8 and FIG. 9, the third open sub-cavity K3 is communicated with the external environment by arranging the plurality of first through holes Via1 on the seventh insulating layer IS7, the fourth open sub-cavity K4 is communicated with the external environment by arranging the plurality of second through holes Via2, and the second open sub-cavity K2 is communicated with the external environment by arranging the plurality of third through holes Via3, so that the pressure tested by the sensing device is atmospheric pressure, that is, absolute pressure.

The sensing device shown in FIG. 8 or FIG. 9 can be used to detect absolute pressure and temperature at the same time, can be used as an acoustic sensor, and can be applied to devices such as microphones. The specific working principles of measuring the temperature and the pressure are similar to that of the sensing device shown in FIG. 2 or FIG. 3. After obtaining a value of the absolute pressure, a frequency (or frequency range) of sound wave can be calculated according to the value of the absolute pressure.

In at least one sensing device provided by the embodiments of the present disclosure, as shown in FIG. 5, FIG. 6 and FIG. 7, the first sensor 1 further includes a first detection structure Y1.

The first sensor 1 further includes a first insulating layer IS1, a first supporting part Z1, a third insulating layer IS3 and a fourth insulating layer IS4. The first insulating layer IS1 is located on a side of the isolation layer 3 close to the first closed sub-cavity F1, the first supporting part Z1 is located between the first insulating layer IS1 and the third insulating layer IS3 and is arranged around the first closed sub-cavity F1, the fourth insulating layer IS4 covers the first electrode layer 11, and the plurality of first thermal deformation structures 12 are in direct contact with the first insulating layer IS1 and the third insulating layer IS3 respectively. The first detection structure Y1 is located on a side of the first electrode layer 11 away from the first closed sub-cavity F1, and an orthographic projection of the first detection structure Y1 on the isolation layer 3 and an orthographic projection of each of the plurality of first thermal deformation structures 12 on the isolation layer 3 do not overlap with each other.

In an exemplary embodiment, materials of the first detection structure Y1 can include piezoelectric materials or piezoresistive materials. Both the piezoelectric materials and the piezoresistive materials can generate changes in current under the action of the pressure, and the function of the pressure intuitively reflected in the sensing device is changes in the deflection of the first electrode layer 11.

In at least one sensing device provided by the embodiments of the present disclosure, as shown in FIG. 5, FIG. 6 and FIG. 7, the second sensor 2 further includes a second detection structure Y2.

The second sensor 2 further includes a fifth insulating layer IS5, a sixth insulating layer IS6, a seventh insulating layer IS7, a second supporting part Z2 and a third supporting part Z3. The second supporting part Z2 is located between the fifth insulating layer IS5 and the sixth insulating layer IS6 and is arranged around the second closed sub-cavity F2, the third supporting part Z3 is located between the second electrode layer 21 and the seventh insulating layer IS7 and is arranged around the first open sub-cavity K1, the second electrode layer 21 is arranged in the first open sub-cavity K1 and is located on a side of the sixth insulating layer IS6 away from the second closed sub-cavity F2, and the plurality of second thermal deformation structures 22 are in direct contact with the second electrode layer 21 and the seventh insulating layer IS7 respectively.

The second detection structure Y2 is arranged in the first open sub-cavity K1 and is in contact with the second electrode layer 21, and an orthographic projection of the second detection structure Y2 on the isolation layer 3 and an orthographic projection of each of the plurality of second thermal deformation structures 22 on the isolation layer 3 do not overlap with each other.

In an exemplary embodiment, materials of the second detection structure Y2 can include piezoelectric materials or piezoresistive materials. Both the piezoelectric materials and the piezoresistive materials can generate changes in current under the action of the pressure, and the function of the pressure intuitively reflected in the sensing device is changes in the deflection of the second electrode layer 21.

In an exemplary embodiment, an orthographic projection of the first detection structure Y1 on the isolation layer 3 overlaps with an orthographic projection of the second detection structure Y2 on the isolation layer 3.

For example, the structures and the materials of the first detection structure Y1 and the second detection structure Y2 are the same.

In an exemplary embodiment, a volume of a cavity structure except the plurality of first thermal deformation structures 12 in the first closed sub-cavity F1 is approximately the same as a volume of the cavity structure in the second closed sub-cavity F2.

Taking the structure of the sensing device shown in FIG. 5 or FIG. 6 as an example, the working principle of the sensing device will be explained in detail. The sensing device shown in FIG. 5 or FIG. 6 can be used to detect relative pressure and temperature at the same time, can be used as a pressure sensor, and can be applied to devices such as electronic watches or unmanned aerial vehicles. The specific working principle is as follows.

Taking the conditions of heating and pressing as an example, when the temperature rises, the heights (d) of the plurality of first thermal deformation structures 12 and the plurality of second thermal deformation structures 22 increase in the direction perpendicular to the plane where the isolation layer 3 is located, so that the plurality of first thermal deformation structures 12 support the deformation of the first electrode layer 11 in a direction away from the isolation layer 3, and the plurality of second thermal deformation structures 22 support the deformation of the second electrode layer 21 in a direction close to the isolation layer 3. The first detection structure Y1 and the second detection structure Y2 are respectively subjected to forces in opposite directions, and a relationship between the forces on the detection structures with an amount of change in deflection is f=λ*Δy, where Δy is an amount of change in deflection, and A is a constant. The first detection structure Y1 and the second detection structure Y2 have deflection changes in opposite directions, a deflection change generated by the first detection structure Y1 is −Δyₜ, and a deflection change generated by the second detection structure Y2 is +Δyₜ.

When the pressure increases, the first detection structure Y1 is deformed in a direction close to the first electrode layer 11 and the second detection structure Y2 is deformed in a direction close to the second electrode layer 21. At this time, the deflection change of the first detection structure Y1 due to pressure increase is +Δyₚ, and the deflection change of the second detection structure Y2 due to pressure increase is +Δyₚ.

According to the above analysis, under the conditions of heating and pressing,

$$an total amount of change in deflection of the first sensor 1 Δ y 1 = Δ {y}_{p} - Δ {y}_{t} ; \qquad formula ( 6 )$$

$$an total amount of change in deflection of the second sensor 2 Δ y 2 = Δ {y}_{p} + Δ {y}_{t} ; \qquad formula ( 7 )$$

according to a relationship between a total amount of change in deflection and the measured current Δy=a*I, where a is a constant, then:

$$Δ y 1 = a * Δ I 1 , Δ y 2 = a * Δ I 2 ; and then \qquad formula ( 8 )$$

$$Δ {y}_{p} - Δ {y}_{t} = a * Δ I 1 ;$$

$$Δ {y}_{p} + Δ {y}_{t} = a * Δ I 2 ; \qquad formula ( 9 )$$

the above formula (8) and formula (9) are added to obtain:

$$2 Δ {y}_{p} = a * Δ I 1 + a * Δ I 2 ; \qquad formula ( 10 )$$

the above formula (8) and formula (9) are subtracted to obtain:

$$2 Δ {y}_{t} = a * Δ I 2 - a * Δ I 1. \qquad formula ( 11 )$$

I1 is a current measured by the first sensor 1, and I2 is a current measured by the second sensor 2, and Δyₚ and Δyₜ can be calculated according to formula (10) and formula (11), where Δyₜ can be referred to as the correlation value of the first parameter (temperature) and Δyₚ can be referred to as the correlation value of the second parameter (pressure). Then a temperature value is calculated according to the preset relationship between Δyₜ and the temperature, and a pressure value is calculated according to a preset relationship between Δyₚ and the pressure.

In at least one sensing device provided by the embodiments of the present disclosure, the second parameter includes pressure.

The pressure includes relative pressure and absolute pressure.

For example, as shown in FIG. 2 to FIG. 6, the relative pressure refers to a difference between the external pressure and the pressure of the closed sub-cavity, and the absolute pressure refers to the external pressure. Taking the structure shown in FIG. 2 as an example, when the volume of the cavity structure in the first closed sub-cavity F1 and the volume of the cavity structure in the second closed sub-cavity F2 are the same and the vibrating films thereof are the same, the relative pressure measured by the first sensor 1 is equal to the relative pressure measured by the second sensor, and both are equal to the difference between the external pressure and the pressure of the closed sub-cavity F2 (assuming that the pressure of the first closed sub-cavity F1 is equal to the pressure of the second closed sub-cavity F2).

In at least one sensing device provided by the embodiments of the present disclosure, as shown in FIG. 10A, FIG. 10B, FIG. 12 and FIG. 13, the first cavity Q1 includes a third closed sub-cavity F3, and the second cavity Q2 includes a fourth closed sub-cavity F4.

The first electrode layer 11 is located on a side of the third closed sub-cavity F3 away from the isolation layer 3, and the second electrode layer 21 is located on a side of the fourth closed sub-cavity F4 away from the isolation layer 3.

In some embodiments, the structures and sizes of the third closed sub-cavity F3 and the fourth closed sub-cavity F4 can be set to be the same.

In some embodiments, the structures of the first sensor 1 and the second sensor 2 in the sensing devices shown in FIG. 10A, FIG. 10B, FIG. 12 and FIG. 13 may be set to be the same.

In some embodiments, the first sensor 1 and the second sensor 2 in the sensing devices shown in FIG. 10A, FIG. 10B, FIG. 12 and FIG. 13 may be arranged symmetrically.

In at least one sensing device provided by the embodiments of the present disclosure, as shown in FIG. 10A, FIG. 10B, FIG. 12 and FIG. 13, the first sensor 1 further comprises a first insulating layer IS1, a third insulating layer IS3, a fourth insulating layer IS4 and a first supporting part Z1. The first insulating layer IS1 covers the isolation layer 3, the first supporting part Z1 is located between the first insulating layer IS1 and the third insulating layer IS3 and is arranged around the third closed sub-cavity F3. The plurality of first thermal deformation structures 12 are in contact with the first insulating layer IS1 and the third insulating layer IS3 respectively, and the fourth insulating layer IS4 is located on a side of the first electrode layer 11 away from the third insulating layer IS3.

The second sensor 2 further includes a fifth insulating layer IS5, a sixth insulating layer IS6, a seventh insulating layer IS7 and a second supporting part Z2. The isolation layer 3 covers the fifth insulating layer IS5, the second supporting part Z2 is located between the fifth insulating layer IS5 and the sixth insulating layer IS6 and is arranged around the fourth closed sub-cavity F4, the plurality of second thermal deformation structures 22 are in contact with the fifth insulating layer IS5 and the sixth insulating layer IS6 respectively, and the second electrode layer 21 is located between the sixth insulating layer IS6 and the seventh insulating layer IS7.

The first insulating layer IS1, the third insulating layer IS3, the fourth insulating layer IS4 and the first supporting part Z1, and the fifth insulating layer IS5, the sixth insulating layer IS6, the seventh insulating layer IS7 and the second supporting part Z2 can be described with reference to the previous descriptions, and will not be repeated here.

In at least one sensing device provided by the embodiments of the present disclosure, as shown in FIG. 10A and FIG. 10B, the first sensor 1 further includes a first sliding electrode HD1. The first sliding electrode HD1 is arranged in the third closed sub-cavity F3 and overlaps with an orthographic projection of the first electrode layer 11 on the isolation layer 3, and the first sliding electrode HD1 is configured to slide in a first direction (for example, an OA direction or a AO direction).

The second sensor 2 further includes a second sliding electrode HD2. The second sliding electrode HD2 is arranged in the fourth closed sub-cavity F4 and overlaps with an orthographic projection of the second electrode layer 21 on the isolation layer 3, and a sliding direction of the first sliding electrode HD1 and a sliding direction of the second sliding electrode HD2 are the same.

For example, in FIG. 10A and FIG. 10B, the first direction is a direction perpendicular to a plane where the isolation layer 3 is located.

The above “overlap with” refers to at least partial overlap, including both partial overlap and complete overlap.

In an exemplary embodiment, the first sliding electrode HD1 is slidably connected to inner walls of the third closed sub-cavity F3. For example, as shown in FIG. 10A and FIG. 10B, when the first sliding electrode HD1 slides in the direction perpendicular to the plane where the isolation layer 3 is located, the first sliding electrode HD1 is slidably connected to the first support portion Z1.

In an exemplary embodiment, the second sliding electrode HD2 is slidably connected to inner walls of the fourth closed sub-cavity F4. For example, as shown in FIG. 10A and FIG. 10B, when the second sliding electrode HD2 slides in the direction perpendicular to the plane where the isolation layer 3 is located, the second sliding electrode HD2 is slidably connected to the second support portion Z2.

When the first sliding electrode HD1 and the second sliding electrode HD2 slide in the direction perpendicular to the plane where the isolation layer 3 is located (for example, the OA direction shown in FIG. 10A), in the first sensor 1, the first sliding electrode HD1 and the first electrode layer 11 serve as two electrodes of the third capacitor, as a position of the first sliding electrode HD1 changes, a distance between the first sliding electrode HD1 and the first electrode layer 11 changes, and a capacitance value of the third capacitor changes. In the second sensor 2, the second sliding electrode HD2 and the second electrode layer 21 serve as two electrodes of the fourth capacitor, and as a distance between the second sliding electrode HD2 and the second electrode layer 21 changes, a capacitance value of the fourth capacitor changes. The first sliding electrode HD1 and the second sliding electrode HD2 are in the same motion state, and an acceleration of the first sliding electrode HD1 and an acceleration of the second sliding electrode HD2 can be calculated according to the change of the capacitance value of the third capacitor and the change of the capacitance value of the fourth capacitor.

In at least one sensing device provided by the embodiments of the present disclosure, as shown in FIG. 10A and FIG. 10B, an orthographic projection of the first sliding electrode HD1 on the isolation layer 3 and an orthographic projection of each of the plurality of first thermal deformation structures 12 on the isolation layer 3 do not overlap with each other, and an orthographic projection of the second sliding electrode HD2 on the isolation layer 3 and an orthographic projection of each of the plurality of second thermal deformation structures 21 on the isolation layer 3 do not overlap with each other.

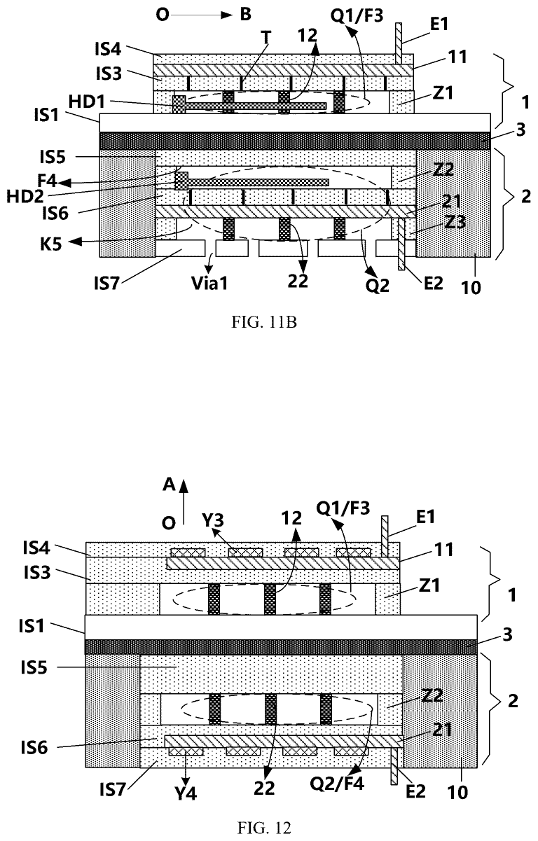

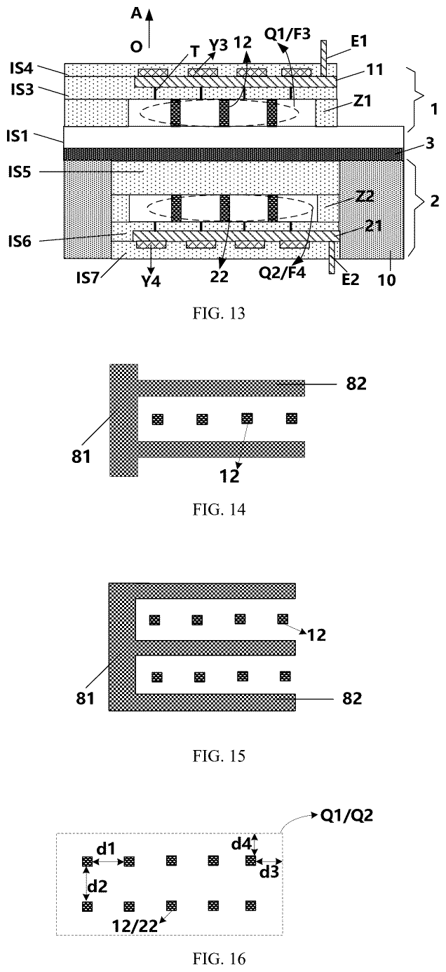

FIG. 14 and FIG. 15 provide schematic top views of two sliding electrodes.

In an exemplary embodiment, the first sliding electrode HD1 and the second sliding electrode HD2 have the same structure.

As shown in FIG. 14 and FIG. 15, the first sliding electrode HD1 and the second sliding electrode HD2 each include a mass block 81 and one or more extension electrodes 82, and the mass block 81 is connected to the extension electrodes 82. As shown in FIG. 10A and FIG. 10B, orthographic projections of the extension electrodes 82 on the isolation layer 3 overlap with the orthographic projection of the first electrode layer 11 or the second electrode layer 21 on the isolation layer 3, the mass block 81 of the first sliding electrode HD1 is slidably connected to the first supporting part Z1, and the mass block 81 of the second sliding electrode HD2 is slidably connected to the second supporting part Z2.

When the mass block 81 of the first sliding electrode HD1 is slidably connected to the first supporting part Z1 and the mass block 81 of the second sliding electrode HD2 is slidably connected to the second supporting part Z2, both the first sliding electrode HD1 and the second sliding electrode HD2 slide in the direction perpendicular to the plane where the isolation layer 3 is located; at this time, the acceleration measured by the sensing device is an acceleration perpendicular to the plane where the isolation layer 3 is located, for example, an acceleration in a vertical direction.

The orthographic projections of the extension electrodes 82 on the isolation layer 3 overlap with the orthographic projection of the first electrode layer 11 or the second electrode layer 21 on the isolation layer 3, which means that the orthographic projections of the extension electrodes 82 of the first sliding electrode HD1 on the isolation layer 3 overlap with the orthographic projection of the first electrode layer 11 on the isolation layer 3, and the orthographic projections of the extension electrodes 82 of the second sliding electrode HD2 on the isolation layer 3 overlap with the orthographic projection of the second electrode layer 21 on the isolation layer 3.

In at least one sensing device provided by the embodiments of the present disclosure, as shown in FIG. 11A and FIG. 11B, the second cavity Q2 further includes a fifth open sub-cavity K5. The fifth open sub-cavity K5 is located on a side of the fourth closed sub-cavity F4 away from the isolation layer 3.

The first sensor 1 further includes a first insulating layer IS1, a third insulating layer IS3, a fourth insulating layer IS4 and a first supporting part Z1. The first insulating layer IS1 covers the isolation layer 3, the first supporting part Z1 is located between the first insulating layer IS1 and the third insulating layer IS3 and is arranged around the third closed sub-cavity F3, the plurality of first thermal deformation structures 12 are in contact with the first insulating layer IS1 and the third insulating layer IS3 respectively, and the fourth insulating layer IS4 is located on a side of the first electrode layer 11 away from the third insulating layer IS3.

The second sensor 2 further includes a fifth insulating layer IS5, a sixth insulating layer IS6, a seventh insulating layer IS7, a second supporting part Z2 and a third supporting part Z3. The isolation layer 3 covers the fifth insulating layer IS5, the second supporting part Z2 is located between the fifth insulating layer IS5 and the sixth insulating layer IS6 and is arranged around the fourth closed sub-cavity F4, the second electrode layer 21 is located in the fifth open sub-cavity K5 and is in contact with the sixth insulating layer IS6, the third supporting part Z3 is located between the second electrode layer 21 and the seventh insulating layer IS7 and is arranged around the fifth open sub-cavity K5, and the plurality of second thermal deformation structures 22 are located in the fifth open sub-cavity K5 and are in contact with the second electrode layer 21 and the seventh insulating layer IS7.

The first insulating layer IS1, the third insulating layer IS3, the fourth insulating layer IS4 and the first supporting part Z1, and the fifth insulating layer IS5, the sixth insulating layer IS6, the seventh insulating layer IS7 and the second supporting part Z2 can be described with reference to the previous descriptions, and will not be repeated here.

In at least one sensing device provided by the embodiments of the present disclosure, as shown in FIG. 11A and FIG. 11B, the first sensor 1 includes a first sliding electrode HD1. The first sliding electrode HD1 is arranged in the third closed sub-cavity F3 and overlaps with an orthographic projection of the first electrode layer 11 on the isolation layer 3, and the first sliding electrode HD1 is configured to slide in a first direction. The first direction is a direction parallel to a plane where the isolation layer 3 is located (for example, an OB direction or a BO direction).

The second sensor 2 further includes a second sliding electrode HD2. The second sliding electrode HD2 is arranged in the fourth closed sub-cavity F4 and overlaps with an orthographic projection of the second electrode layer 21 on the isolation layer 3, and a sliding direction of the first sliding electrode HD1 and a sliding direction of the second sliding electrode HD2 are the same.

In an exemplary embodiment, the first sliding electrode HD1 is slidably connected to inner walls of the third closed sub-cavity F3. For example, as shown in FIG. 11A and FIG. 11B, when the first sliding electrode HD1 slides in the direction parallel to the plane where the isolation layer 3 is located (for example, the OB direction), the first sliding electrode HD1 is slidably connected to the first insulating layer IS1.

In an exemplary embodiment, the second sliding electrode HD2 is slidably connected to inner walls of the fourth closed sub-cavity F4. For example, as shown in FIG. 11A and FIG. 11B, when the second sliding electrode HD2 slides in the direction parallel to the plane where the isolation layer 3 is located (for example, the OB direction), the second sliding electrode HD2 is slidably connected to the sixth insulating layer IS6.

When the first sliding electrode HD1 and the second sliding electrode HD2 slide in the direction parallel to the plane where the isolation layer 3 is located (for example, the OB direction shown in FIG. 11A), in the first sensor 1, the first sliding electrode HD1 and the first electrode layer 11 serve as two electrodes of the third capacitor, as a position of the first sliding electrode HD1 changes, an opposite area between the first sliding electrode HD1 and the first electrode layer 11 changes, and a capacitance value of the third capacitor changes. In the second sensor 2, the second sliding electrode HD2 and the second electrode layer 21 serve as two electrodes of the fourth capacitor, and as a position of the second sliding electrode HD2 changes, a capacitance value of the fourth capacitor changes. The first sliding electrode HD1 and the second sliding electrode HD2 are in the same motion state, and an acceleration of the first sliding electrode HD1 and an acceleration of the second sliding electrode HD2 can be calculated according to the change of the capacitance value of the third capacitor and the change of the capacitance value of the fourth capacitor.

In at least one sensing device provided by the embodiments of the present disclosure, as shown in FIG. 11A and FIG. 11B, an orthographic projection of the first sliding electrode HD1 on the isolation layer 3 and an orthographic projection of each of the plurality of first thermal deformation structures 12 on the isolation layer 3 do not overlap with each other, and an orthographic projection of the second sliding electrode HD2 on the isolation layer 3 and an orthographic projection of each of the plurality of second thermal deformation structures 22 on the isolation layer 3 do not overlap with each other.

FIG. 14 and FIG. 15 provide schematic top views of two sliding electrodes.

In an exemplary embodiment, the first sliding electrode HD1 and the second sliding electrode HD2 have the same structure.

As shown in FIG. 14 and FIG. 15, the first sliding electrode HD1 and the second sliding electrode HD2 each include a mass block 81 and one or more extension electrodes 82. The mass block 81 is connected to the extension electrodes 82, orthographic projections of the extension electrodes 82 on the isolation layer 3 overlap with the orthographic projection of the first electrode layer 11 or the second electrode layer 21 on the isolation layer 3, as shown in FIG. 11A and FIG. 11B. The mass block 81 of the first sliding electrode HD1 is slidably connected to the first insulating layer IS1, the mass block 81 of the second sliding electrode HD2 is slidably connected to the sixth insulating layer IS6, the seventh insulating layer IS7 is provided with a plurality of first through holes Via1, and an orthographic projection of each of the plurality of second thermal deformation structures 22 on the isolation layer 3 and a region surrounded by an orthographic projection of an outer contour of each of the plurality of first through holes Via1 on the isolation layer 3 do not overlap with each other.

When the mass block 81 of the first sliding electrode HD1 is slidably connected to the first insulating layer IS1 and the mass block 81 of the second sliding electrode HD2 is slidably connected to the sixth insulating layer IS6, both the first sliding electrode HD1 and the second sliding electrode HD2 slide in the direction parallel to the plane where the isolation layer 3 is located; at this time, the acceleration measured by the sensing device is an acceleration parallel to the plane where the isolation layer 3 is located, for example, an acceleration in a horizontal direction.

In at least one sensing device provided by the embodiments of the present disclosure, as shown in FIG. 10A to FIG. 11B, the first sliding electrode HD1 and the second sliding electrode HD2 are the same. The first direction is the direction perpendicular to the plane where the isolation layer 3 is located (for example, the OA direction or the AO direction), or the first direction is the direction parallel to the plane where the isolation layer 3 is located (for example, the OB direction or the BO direction).

As shown in FIG. 10A and FIG. 10B, when the first direction is the direction perpendicular to the plane where the isolation layer 3 is located (for example, the OA direction or the AO direction), a size of the mass block 81 in the direction perpendicular to the plane where the isolation layer 3 is located is less than a size of a cavity in which the mass block is located in the direction perpendicular to the plane where the isolation layer 3 is located.

For example, a size of the mass block 81 of the first sliding electrode HD1 in the direction perpendicular to the plane where the isolation layer 3 is located is less than a size of the first cavity Q1 in the direction perpendicular to the plane where the isolation layer 3 is located, that is, a height of the mass block 81 in the OA direction is less than a height of the first cavity Q1 in the OA direction.

For another example, a size of the mass block 81 of the second sliding electrode HD2 in the direction perpendicular to the plane where the isolation layer 3 is located is less than a size of the second cavity Q2 in the direction perpendicular to the plane where the isolation layer 3 is located, that is, a height of the mass block 81 in the OA direction is less than a height of the second cavity Q2 in the OA direction.

As shown in FIG. 11A and FIG. 11B, when the first direction is the direction parallel to the plane where the isolation layer 3 is located (for example, the OB direction or the BO direction), sizes of the first sliding electrode HD1 and the second sliding electrode HD2 in the direction parallel to the plane where the isolation layer 3 is located are less than sizes of cavities in which the first sliding electrode and the second sliding electrode are located in the direction parallel to the plane where the isolation layer 3 is located.

For example, a size of the first sliding electrode HD1 in the direction parallel to the plane where the isolation layer 3 is located is less than the size of the first cavity Q1 in the direction parallel to the plane where the isolation layer 3 is located, that is, a length of the first sliding electrode HD1 in the OB direction is less than a length of the first cavity Q1 in the OB direction.

For another example, a size of the second sliding electrode HD2 in the direction parallel to the plane where the isolation layer 3 is located is less than the size of the second cavity Q2 in the direction parallel to the plane where the isolation layer 3 is located, that is, a length of the second sliding electrode HD2 in the OB direction is less than a length of the second cavity Q2 in the OB direction.

In an exemplary embodiment, regardless of whether the first direction is the direction perpendicular to the plane where the isolation layer 3 is located or the first direction is the direction parallel to the plane where the isolation layer 3 is located, sizes of the first sliding electrode HD1 and the second sliding electrode HD2 in the direction parallel to the plane where the isolation layer 3 is located are less than sizes of cavities in which the first sliding electrode and the second sliding electrode are located in the direction parallel to the plane where the isolation layer 3 is located, and sizes of the first sliding electrode HD1 and the second sliding electrode HD2 in the direction perpendicular to the plane where the isolation layer 3 is located are less than sizes of cavities in which the first sliding electrode and the second sliding electrode are located in the direction perpendicular to the plane where the isolation layer 3 is located, which is more conducive to the smooth sliding of the sliding electrodes and avoids the influence of redundant friction resistance on the sliding. The drawings provided by the embodiments of the present disclosure are all drawn by taking this as an example.

Taking the structure of the sensing device shown in FIG. 10A or FIG. 10B as an example, the working principle of the sensing device will be explained in detail. The sensing device shown in FIG. 10A or FIG. 10B can be used to detect acceleration and temperature at the same time, can be used as a motion sensor, and can be applied to devices such as accelerometers or gyroscopes. The specific working principle is as follows.

Taking the conditions of heating and acceleration (for example, an acceleration in the OA direction) as an example, when the temperature rises, the heights (d) of the plurality of first thermal deformation structures 12 and the plurality of second thermal deformation structures 22 increase in the direction perpendicular to the plane where the isolation layer 3 is located, that is, the plurality of first thermal deformation structures 12 support the deformation of the first electrode layer 11 in a direction away from the isolation layer 3, and the plurality of second thermal deformation structures 22 support the deformation of the second electrode layer 21 in the direction away from the isolation layer 3, so that a distance d between the two electrodes of the third capacitor increases, and a distance d between the two electrodes of the fourth capacitor increases. According to the calculation formula of the capacitor C=εs/4πkd, where C is the capacitance value, & is a dielectric constant, s is an opposite area between the two electrodes, k is a constant, and d is the distance between the two electrodes, C₃ₜ increases (that is, +C₃ₜ) and C₄ₜ increases (that is, +C₄ₜ), where C₃ₜ represents a change of the capacitance value of the third capacitor caused by temperature rise, and C₄ₜ represents a change of the capacitance value of the fourth capacitor caused by temperature rise.

When the acceleration of the sensing device in the OA direction increases, the first sliding electrode HD1 moves in the OA direction, and the second sliding electrode HD2 moves in the OA direction, the distance between the first sliding electrode HD1 and the first electrode layer 11 decreases, and the distance between the second sliding electrode HD2 and the second electrode layer 21 increases, and thus C₃ₐ increases (that is, +C₃ₐ) and C₄ₐ decreases (that is, —C₄ₐ), where C₃ₐ represents a change of the capacitance value of the third capacitor caused by acceleration increase, and C₄ₐ represents a change of the capacitance value of the fourth capacitor caused by acceleration increase.

According to the above analysis, under the conditions of heating and acceleration,

$$an amount of change in capacitance of the first sensor 1 Δ {C}_{1} = {C}_{3 t} + {C}_{3 a} ; \qquad formula ( 12 )$$

$$an amount of change in capacitance of the second sensor 2 Δ {C}_{2} = {C}_{4 t} - {C}_{4 a} ; \qquad formula ( 13 )$$

since the plurality of first thermal deformation structure 12 and the plurality of second thermal deformation structure 22 are the same, C₃ₜ=C₄ₜ−Cₜ; and since the volumes of the cavity structures of the two closed sub-cavities are the same, the first sliding electrode HD1 and the second sliding electrode HD2 are the same, C₃ₐ−C₄ₐ=Cₐ;
the above formula (12) and formula (13) are added to obtain:

$$Δ {C}_{1} + Δ {C}_{2} = 2 {C}_{t} ; \qquad formula ( 14 )$$

the above formula (12) and formula (13) are subtracted to obtain:

$$Δ {C}_{2} - Δ {C}_{1} = 2 {C}_{a} . \qquad formula ( 15 )$$

There is a preset relationship between the amount of change in capacitance AC and an amount of change in current ΔI, and δ is a constant, that is,

$$Δ C = δ * Δ I ; \qquad formula ( 16 )$$

then ΔC₁=δ*ΔI₁, ΔC₂=δ*ΔI₂; ΔI₁ and ΔI₂ can be directly tested by the circuit external to the sensing device, and then specific values of ΔC₁ and ΔC₂ can be calculated. Combined with the above formula (14) and formula (15) and the specific values of ΔC₁ and ΔC₂, specific values of Cₜ and Cₐ can be calculated, where Cₜ can be referred to as the correlation value of the first parameter (temperature) and Cₐ can be referred to as the correlation value of the second parameter (acceleration). Then a temperature value is calculated according to a preset relationship between Cₜ and the temperature, and an acceleration value is calculated according to a preset relationship between Cₐ and the acceleration.

It should be noted that the value of Cₐ is related to the distance d between the sliding electrode and the electrode layer, and Δd−(Δat²)/2, where Δd is an amount of change in the distance d, which also represents a sliding distance of the sliding electrode, Δa is an amount of change in the acceleration, and tis a motion time; and thus the amount of change in the acceleration can be calculated using this formula.

Taking the structure of the sensing device shown in FIG. 11A or FIG. 11B as an example, the working principle of the sensing device will be explained in detail. The sensing device shown in FIG. 11A or FIG. 11B can be used to detect acceleration and temperature at the same time, can be used as a motion sensor, and can be applied to devices such as accelerometers or gyroscopes. The specific working principle is as follows.

Taking the conditions of heating and acceleration (for example, an acceleration in the OB direction) as an example, when the temperature rises, the heights (d) of the plurality of first thermal deformation structures 12 and the plurality of second thermal deformation structures 22 increase in the direction perpendicular to the plane where the isolation layer 3 is located, that is, the plurality of first thermal deformation structures 12 support the deformation of the first electrode layer 11 in a direction away from the isolation layer 3, and the plurality of second thermal deformation structures 22 support the deformation of the second electrode layer 21 in a direction close to the isolation layer 3, so that a distance d between the two electrodes of the third capacitor increases, and a distance d between the two electrodes of the fourth capacitor decreases. According to the calculation formula of the capacitor C=εs/4πkd, where C is the capacitance value, & is a dielectric constant, s is an opposite area between the two electrodes, k is a constant, and d is the distance between the two electrodes, C₃ₜ increases (that is, +C₃ₜ) and C₄ₜ decreases (that is, —C₄ₜ), where C₃ₜ represents a change of the capacitance value of the third capacitor caused by temperature rise, and C₄ₜ represents a change of the capacitance value of the fourth capacitor caused by temperature rise.

When the acceleration of the sensing device in the OB direction increases, the first sliding electrode HD1 moves in the OB direction, and the second sliding electrode HD2 moves in the OB direction, the opposite area between the first sliding electrode HD1 and the first electrode layer 11 increases, and the opposite area between the second sliding electrode HD2 and the second electrode layer 21 increases, and thus C₃ₐ increases (that is, +C₃ₐ) and C₄ₐ increases (that is, +C₄ₐ), where C₃ₐ represents a change of the capacitance value of the third capacitor caused by acceleration increase, and C₄ₐ represents a change of the capacitance value of the fourth capacitor caused by acceleration increase.

According to the above analysis, under the conditions of heating and acceleration,

$$an amount of change in capacitance of the first sensor 1 Δ {C}_{1} = {C}_{3 t} + {C}_{3 a} ; \qquad formula ( 17 )$$

$$an amount of change in capacitance of the second sensor 2 Δ {C}_{2} = - {C}_{4 t} - {C}_{4 a} ; \qquad formula ( 18 )$$

since the plurality of first thermal deformation structure 12 and the plurality of second thermal deformation structure 22 are the same, C₃ₜ=C₄ₜ=Cₜ; and since the volumes of the cavity structures of the two closed sub-cavities are the same, the first sliding electrode HD1 and the second sliding electrode HD2 are the same, C₃ₐ−C₄ₐ=Cₐ;
the above formula (17) and formula (18) are added to obtain:

$$Δ {C}_{1} + Δ {C}_{2} = 2 {C}_{a} ; \qquad formula ( 19 )$$

the above formula (17) and formula (18) are subtracted to obtain:

$$Δ {C}_{2} - Δ {C}_{1} = 2 {C}_{t} . \qquad formula ( 20 )$$

There is a preset relationship between the amount of change in capacitance AC and an amount of change in current ΔI, and δ is a constant, that is,

$$Δ C = δ * Δ I ; \qquad formula ( 21 )$$

then ΔC₁=δ*ΔI₁, ΔC₂=δ*ΔI₂; ΔI₁ and ΔI₂ can be directly tested by the circuit external to the sensing device, and then specific values of ΔC₁ and ΔC₂ can be calculated. Combined with the above formula (19) and formula (20) and the specific values of ΔC₁ and ΔC₂, specific values of Cₜ and Cₐ can be calculated, where Cₜ can be referred to as the correlation value of the first parameter (temperature) and Cₐ can be referred to as the correlation value of the second parameter (acceleration). Then a temperature value is calculated according to a preset relationship between Cₜ and the temperature, and an acceleration value is calculated according to a preset relationship between Cₐ and the acceleration.

In at least one sensing device provided by the embodiments of the present disclosure, as shown in FIG. 12 and FIG. 13, the first sensor 1 further includes a third detection structure Y3. The third detection structure Y3 is arranged on a side of the first electrode layer 11 away from the third closed sub-cavity F3, and an orthographic projection of the third detection structure Y3 on the isolation layer 3 and an orthographic projection of each of the plurality of first thermal deformation structures 12 on the isolation layer 3 do not overlap with each other. The second sensor 2 further includes a fourth detection structure Y4. The fourth detection structure Y4 is arranged on a side of the second electrode layer 21 away from the fourth closed sub-cavity F4, an orthographic projection of the fourth detection structure Y4 on the isolation layer 3 and an orthographic projection of each of the plurality of second thermal deformation structures 22 on the isolation layer 3 do not overlap with each other, and the orthographic projection of the third detection structure Y3 on the isolation layer 3 overlaps with the orthographic projection of the fourth detection structure Y4 on the isolation layer 3.

In an exemplary embodiment, materials of the third detection structure Y3 and the fourth detection structure Y4 can include piezoelectric materials or piezoresistive materials. Both the piezoelectric materials and the piezoresistive materials can generate changes in current under the action of the pressure, and the function of the pressure intuitively reflected in the sensing device is changes in the deflection of the first electrode layer 11 or the second electrode layer 21.

In an exemplary embodiment, an orthographic projection of the third detection structure Y3 on the isolation layer 3 overlaps with an orthographic projection of the fourth detection structure Y4 on the isolation layer 3.

For example, the structures and the materials of the third detection structure Y3 and the fourth detection structure Y4 are the same.

In an exemplary embodiment, a volume of a cavity structure except the plurality of first thermal deformation structures 12 in the third closed sub-cavity F3 is approximately the same as a volume of a cavity structure except the plurality of second thermal deformation structures 22 in the fourth closed sub-cavity F4, and the plurality of first thermal deformation structures 12 and the plurality of second thermal deformation structures 22 are the same.

In an exemplary embodiment, the first sensor 1 and the second sensor 2 in the sensing device shown in FIG. 12 and FIG. 13 are symmetrically arranged.

Taking the structure of the sensing device shown in FIG. 12 or FIG. 13 as an example, the working principle of the sensing device will be explained in detail. The sensing device shown in FIG. 12 or FIG. 13 can be used to detect acceleration and temperature at the same time, can be used as a motion sensor, and can be applied to devices such as accelerometers or gyroscopes. The specific working principle is as follows.

Taking the conditions of heating and acceleration (for example, an acceleration in the OA direction) as an example, when the temperature rises, the heights (d) of the plurality of first thermal deformation structures 12 and the plurality of second thermal deformation structures 22 increase in the direction perpendicular to the plane where the isolation layer 3 is located, that is, the plurality of first thermal deformation structures 12 support the deformation of the first electrode layer 11 in a direction away from the isolation layer 3, and the plurality of second thermal deformation structures 22 support the deformation of the second electrode layer 21 in the direction away from the isolation layer 3. The third detection structure Y3 and the fourth detection structure Y4 are respectively subjected to forces in opposite directions, and a relationship between the forces on the detection structures with an amount of change in deflection is f−λ*Δy, where Δy is an amount of change in deflection, and λ is a constant. The third detection structure Y3 and the fourth detection structure Y4 have deflection changes in opposite directions, a deflection change generated by the third detection structure Y3 is −Δyₜ, and a deflection change generated by the fourth detection structure Y4 is +Δyₜ.

When the acceleration of the sensing device in the OA direction increases, the third detection structure Y3 and the fourth detection structure Y4 are deformed in the AO direction under the action of motion resistance (for example, air resistance). At this time, the deflection change of the third detection structure Y3 is +Δyₐ, and the deflection change of the fourth detection structure Y4 is +Δyₐ.

According to the above analysis, under the conditions of heating and acceleration,

$$a total amount of change in deflection of the first sensor 1 Δ y 1 = Δ {y}_{a} - Δ {y}_{t} ; \qquad formula ( 22 )$$

$$a total amount of change in deflection of the second sensor 2 Δ y 2 = Δ {y}_{a} + Δ {y}_{t} ; \qquad formula ( 23 )$$

according to a relationship between a total amount of change in deflection and the measured current Δy=a*I, where a is a constant, then:

$$Δ y 1 = a * Δ I 1 , Δ y 2 = a * Δ I 2 ; and then \qquad formula ( 24 )$$

$$Δ {y}_{a} - Δ {y}_{t} = a * Δ I 1 ;$$

$$Δ {y}_{a} + Δ {y}_{t} = a * Δ I 2 ; \qquad formula ( 25 )$$

the above formula (24) and formula (25) are added to obtain:

$$2 Δ {y}_{a} = a * Δ I 1 + a * Δ I 2 ; \qquad formula ( 26 )$$

the above formula (24) and formula (25) are subtracted to obtain:

$$2 Δ {y}_{t} = a * Δ I 2 - a * Δ I 1. \qquad formula ( 27 )$$

I1 is a current measured by the first sensor 1, and I2 is a current measured by the second sensor 2, and Δyₐ and Δyₜ can be calculated according to formula (26) and formula (27), where Δyₜ can be referred to as the correlation value of the first parameter (temperature) and Δyₐ can be referred to as the correlation value of the second parameter (acceleration). Then a temperature value is calculated according to the preset relationship between Δyₜ and the temperature, and an acceleration value is calculated according to a preset relationship between Δyₐ and the acceleration.

In at least one sensing device provided by the embodiments of the present disclosure, the second parameter includes acceleration.

In at least one sensing device provided by the embodiments of the present disclosure, materials and structures of the first plurality of thermal deformation structures 12 and the plurality of second thermal deformation structures 22 are the same.

In at least one sensing device provided by the embodiments of the present disclosure, orthographic projections of the first plurality of thermal deformation structures 12 on the isolation layer 3 overlap with orthographic projections of the plurality of second thermal deformation structures 22 on the isolation layer 3.

In at least one sensing device provided by the embodiments of the present disclosure, as shown in FIG. 16, the plurality of first thermal deformation structures 12 and the plurality of second thermal deformation structures 22 each include a plurality of thermal deformation patterns, and a distance between any two adjacent thermal deformation patterns is equal.

For example, for the plurality of first thermal deformation structures 12 and the plurality of second thermal deformation structures 22, a distance d1 between two adjacent thermal deformation patterns arranged in a row direction is equal to a distance d2 between two adjacent thermal deformation patterns arranged in a column direction.

For example, a distance d3 between a thermal deformation pattern close to an edge of the cavity structure and the cavity structure in the row direction is equal to a distance d4 between the thermal deformation pattern and the cavity structure in the column direction.

In the first sensor 1, the distance d3 between a thermal deformation pattern in a first thermal deformation structure 12 close to an edge of the first cavity Q1 and the first cavity Q1 in the row direction is equal to the distance d4 between the thermal deformation pattern and the first cavity Q1 in the column direction.

In the second sensor 2, the distance d3 between a thermal deformation pattern in a second thermal deformation structure 22 close to an edge of the second cavity Q2 and the second cavity Q2 in the row direction is equal to the distance d4 between the thermal deformation pattern and the second cavity Q2 in the column direction.

In the embodiments of the present disclosure, by arranging the distance between any two adjacent thermal deformation patterns to be equal, the distribution uniformity of the plurality of first thermal deformation structures 12 in the first cavity Q1 and the distribution uniformity of the plurality of second thermal deformation structures 22 in the second cavity Q2 can be improved, thereby improving the sensitivity and accuracy of temperature detection of the thermal deformation structures.

In at least one sensing device provided by the embodiments of the present disclosure, the materials of the plurality of first thermal deformation structures 12 and the plurality of second thermal deformation structures 22 include thermoelastic materials.

The plurality of first thermal deformation structures 12 and the plurality of second thermal deformation structures 22 can undergo thermal deformation (or thermal expansion) under the condition of temperature rise.

For example, the thermoelastic materials can further include reticular high molecular materials with relatively high thermoelasticity and thermoplastic elastomers such as polyolefin elastomers and rubber.

In at least one sensing device provided by the embodiments of the present disclosure, the second sensor 2 is embedded in a substrate 10, and the isolation layer 3 covers the substrate 10. The sensing device further includes a plurality of connection electrodes for transmitting

electrical signals, for example, a connection electrode E1, a connection electrode E2 and connection electrodes E3 shown in FIG. 2. The connection electrode E1 is electrically connected to the first electrode layer 11, the connection electrode E2 is electrically connected to the second electrode layer 21, and the connection electrodes E3 are electrically connected to the common electrode layer 4. The sensing device also includes other structures and components. This specification only introduces structures and components related to inventive points, and other structures and components included in the sensing device can refer to the introduction in the related art.

The embodiments of the present disclosure provide a method for preparing a sensing device. Taking the sensing device shown in FIG. 3 as an example, the specific preparation method is as follows.
1. As shown in FIG. 17, an isolation layer 3, a second insulating layer IS2, a common electrode layer 4, a first insulating layer IS1 and a sacrificial layer SL are sequentially formed on a substrate 1.
2. As shown in FIG. 18, pattern processing is performed on the sacrificial layer SL to obtain a plurality of voids arranged on the sacrificial layer SL.

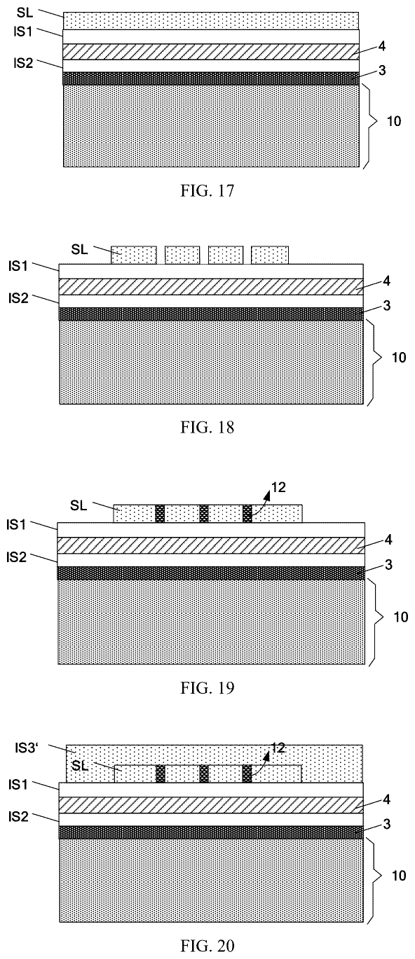

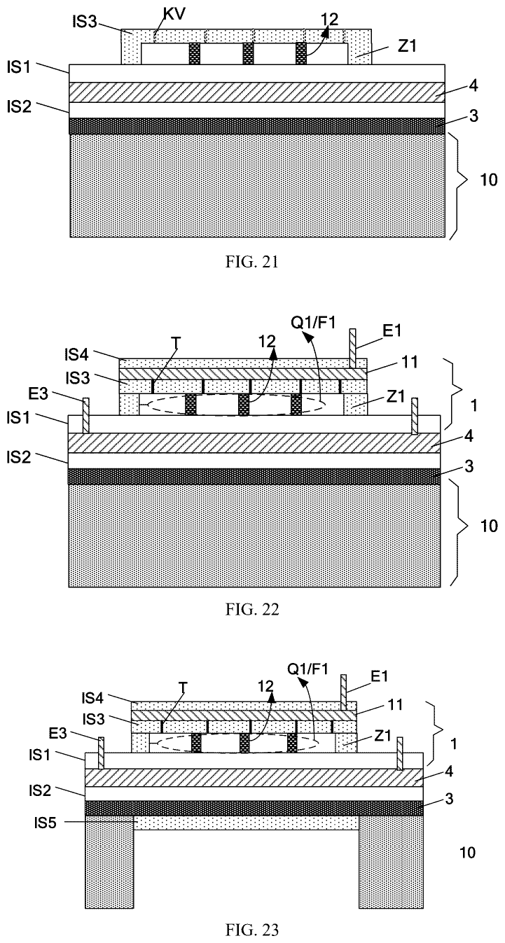

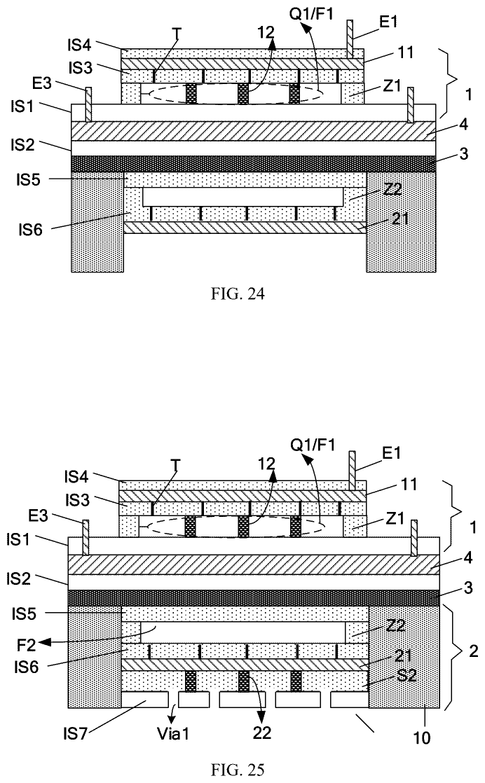

Materials of the sacrificial layer SL can be inorganic materials, for example, one of silicon nitride, silicon oxide or silicon oxynitride. The sacrificial layer SL can be patterned through an etching process.
3. As shown in FIG. 19, a plurality of first thermal deformation structures 12 are formed in the plurality of voids of the sacrificial layer SL.
4. As shown in FIG. 20, a third insulating film IS3′ is formed.
5. As shown in FIG. 21, pattern processing is performed on the third insulating film IS3′ to obtain a third insulating layer IS3, a first supporting part Z1, and a plurality of hollowed-out etching holes KV arranged on the third insulating layer IS3, where the third insulating layer IS3 and the first supporting part Z1 are an integrated structure.
6. As shown in FIG. 21, etching liquid is released through the etching holes KV, and a first cavity Q1 is formed.
7. As shown in FIG. 22, a first electrode layer 11 is formed and the plurality of hollowed-out etching holes KV are filled at the same time to form a plurality of etching holes T (etching holes after filling are marked with T, and etching holes before filling are marked with KV).
8. As shown in FIG. 22, a fourth insulating layer IS4, a connection electrode E1 and connection electrodes E3 are sequentially formed.
9. As shown in FIG. 23, a hollow structure is formed on the substrate 10, and a fifth insulating layer IS5 is formed in the hollow structure.
10. As shown in FIG. 24, an insulating film is formed on a side of the fifth insulating layer IS5 away from the isolation layer 3, pattern processing is performed on the insulating film to obtain a sixth insulating layer IS6, a second supporting part Z2 and a plurality of hollowed-out etching holes KV arranged on the sixth insulating layer IS6, and the etching liquid is released through the etching holes KV to form a second closed sub-cavity F2.
11. As shown in FIG. 24, a second electrode layer 21 is formed and the hollowed-out etching holes KV are filled at the same time.
12. As shown in FIG. 25, a sacrificial layer S2 is formed, pattern processing is performed on the sacrificial layer S2 to obtain a plurality of voids arranged on the sacrificial layer S2, and a plurality of second thermal deformation structures 22 are formed in the plurality of voids.
13. As shown in FIG. 25, a seventh insulating layer IS7 with a plurality of first via holes Via1 is formed, and the etching liquid is released through the first via holes Via1 to form a first open sub-cavity K1 shown in FIG. 3.

The preparation method of the above sensing device also includes other processes and steps. Only preparation methods of structures and components related to the inventive points are introduced here, and the specific preparation process details of the sensing device can also refer to the introduction in the related art.

It should be noted that the preparation methods of other sensing devices are similar to those of the sensing device shown in FIG. 3, and will not be repeated here.

The above is only the specific implementation of the present disclosure, but the protection scope of the present disclosure is not limited to this. Any skilled person familiar with this technical field can easily think of changes or replacements within the technical scope disclosed in the present disclosure, which should be covered within the protection scope of the present disclosure. Therefore, the protection scope of the present disclosure should be based on the protection scope of the claims.

1. A sensing device, comprising an isolation layer, and a first sensor and a second sensor respectively located on both sides of the isolation layer, wherein an orthographic projection of the first sensor on the isolation layer overlaps with an orthographic projection of the second sensor on the isolation layer;
the first sensor comprises a first cavity, a first electrode layer and a plurality of first thermal deformation structures, wherein the first electrode layer is arranged on a side of the first cavity away from the isolation layer, and the plurality of first thermal deformation structures are arranged in the first cavity and are in contact with two inner walls opposite to the first cavity; and
the second sensor comprises a second cavity, a second electrode layer and a plurality of second thermal deformation structures, wherein the second electrode layer is arranged on a side of the isolation layer away from the first cavity, and the plurality of second thermal deformation structures are arranged in the second cavity and are in contact two inner walls opposite to the second cavity.

2. The sensing device according to claim 1, wherein the first cavity comprises a first closed sub-cavity, and the second cavity comprises a second closed sub-cavity and a first open sub-cavity, wherein the first open sub-cavity is located on a side of the second closed sub-cavity away from the isolation layer; and
the plurality of second thermal deformation structures are arranged in the first open sub-cavity and are in contact with two inner walls opposite to the first open sub-cavity, and the second electrode layer is arranged on a side of the second closed sub-cavity away from the isolation layer.

3. The sensing device according to claim 2, wherein a volume of a cavity structure in the first closed sub-cavity is approximately equal to a volume of a cavity structure in the second closed sub-cavity.

4. The sensing device according to claim 2, wherein the second electrode layer is arranged between the second closed sub-cavity and the first open sub-cavity; or
the second electrode layer is arranged on a side of the first open sub-cavity close to the second closed sub-cavity.

5. The sensing device according to claim 1, wherein the first cavity comprises a second open sub-cavity, and the second cavity comprises a third open sub-cavity and a fourth open sub-cavity, wherein the third open sub-cavity is arranged on a side of the fourth open sub-cavity away from the isolation layer; and
the plurality of second thermal deformation structures are arranged in the third open sub-cavity and are in contact with two inner walls opposite to the third open sub-cavity, and the second electrode layer is arranged on a side of the third open sub-cavity close to the fourth open sub-cavity and is in contact with the plurality of second thermal deformation structures.

6. The sensing device according to claim 2, wherein the sensing device further comprises a common electrode layer, a first insulating layer and a second insulating layer, wherein the first insulating layer is located on a side of the common electrode layer close to the first cavity, and the second insulating layer is located between the common electrode layer and the isolation layer; and
the common electrode layer is arranged between the first cavity and the second cavity, the first electrode layer and the common electrode layer are respectively used as two electrodes of a first capacitor, and the second electrode layer and the common electrode layer are respectively used as two electrodes of a second capacitor.

7. The sensing device according to claim 6, wherein the first sensor further comprises a first supporting part, a third insulating layer and a fourth insulating layer, wherein the first supporting part is located between the first insulating layer and the third insulating layer and is arranged around the first cavity, the fourth insulating layer covers the first electrode layer, and the plurality of first thermal deformation structures are in direct contact with the first insulating layer and the third insulating layer respectively.

8. The sensing device according to claim 7, wherein in response to the first cavity comprising the first closed sub-cavity and the second cavity comprising the second closed sub-cavity and the first open sub-cavity, the plurality of second thermal deformation structures are arranged in the first open sub-cavity and are in contact with the two inner walls opposite to the first open sub-cavity;
the second sensor further comprises a fifth insulating layer, a sixth insulating layer, a seventh insulating layer, a second supporting part and a third supporting part, wherein the second supporting part is arranged between the fifth insulating layer and the sixth insulating layer and is arranged around the second closed sub-cavity, the third supporting part is arranged between the second electrode layer and the seventh insulating layer and is arranged around the first open sub-cavity, and the second electrode layer is arranged in the first open sub-cavity and is located on a side of the sixth insulating layer away from the second closed sub-cavity; and
the plurality of second thermal deformation structures are in direct contact with the second electrode layer and the seventh insulating layer respectively, the seventh insulating layer is provided with a plurality of first through holes, and an orthographic projection of each of the plurality of second thermal deformation structures on the isolation layer and a region surrounded by an orthographic projection of an outer contour of each of the plurality of first through holes on the isolation layer do not overlap with each other.

9. The sensing device according to claim 7, wherein in response to the first cavity comprising a second open sub-cavity and the second cavity comprising the third open sub-cavity and the fourth open sub-cavity, the plurality of second thermal deformation structures are arranged in the third open sub-cavity and are in contact with the two inner walls opposite to the third open sub-cavity;
the second sensor further comprises a fifth insulating layer, a sixth insulating layer, a seventh insulating layer, a second supporting part and a third supporting part, wherein the second supporting part is arranged between the fifth insulating layer and the sixth insulating layer and is arranged around the fourth open sub-cavity, the third supporting part is arranged between the second electrode layer and the seventh insulating layer and is arranged around the third open sub-cavity, and the second electrode layer is arranged in the third open sub-cavity and is located on a side of the sixth insulating layer away from the fourth open sub-cavity; and
the plurality of second thermal deformation structures are in direct contact with the second electrode layer and the seventh insulating layer respectively, the seventh insulating layer is provided with a plurality of first through holes, the sixth insulating layer is provided with a plurality of second through holes, and the plurality of second through holes pass through the second electrode layer, and an orthographic projection of each of the plurality of second thermal deformation structures on the isolation layer does not overlap with a region surrounded by an orthographic projection of an outer contour of each of the plurality of first through holes on the isolation layer and a region surrounded by an orthographic projection of an outer contour of each of the plurality of second through holes on the isolation layer.

10. The sensing device according to claim 9, wherein the first sensor comprises a plurality of third through holes, wherein the plurality of third through holes sequentially pass through the fourth insulating layer, the first electrode layer and the third insulating layer, and an orthographic projection of each of the plurality of first thermal deformation structures on the isolation layer and a region surrounded by an orthographic projection of an outer contour of each of the plurality of third through holes on the isolation layer do not overlap with each other.

11. The sensing device according to claim 2, wherein the first sensor further comprises a first detection structure;
the first sensor further comprises a first insulating layer, a first supporting part, a third insulating layer and a fourth insulating layer, wherein the first insulating layer is located on a side of the isolation layer close to the first closed sub-cavity, the first supporting part is located between the first insulating layer and the third insulating layer and is arranged around the first closed sub-cavity, the fourth insulating layer covers the first electrode layer, and the plurality of first thermal deformation structures are in direct contact with the first insulating layer and the third insulating layer respectively; and
the first detection structure is located on a side of the first electrode layer away from the first closed sub-cavity, and an orthographic projection of the first detection structure on the isolation layer and an orthographic projection of each of the plurality of first thermal deformation structures on the isolation layer do not overlap with each other.

12. The sensing device according to claim 11, wherein the second sensor further comprises a second detection structure;
the second sensor further comprises a fifth insulating layer, a sixth insulating layer, a seventh insulating layer, a second supporting part and a third supporting part, wherein the second supporting part is located between the fifth insulating layer and the sixth insulating layer and is arranged around the second closed sub-cavity, the third supporting part is located between the second electrode layer and the seventh insulating layer and is arranged around the first open sub-cavity, the second electrode layer is arranged in the first open sub-cavity and is located on a side of the sixth insulating layer away from the second closed sub-cavity, and the plurality of second thermal deformation structures are in direct contact with the second electrode layer and the seventh insulating layer respectively; and
the second detection structure is arranged in the first open sub-cavity and is in contact with the second electrode layer, and an orthographic projection of the second detection structure on the isolation layer and an orthographic projection of each of the plurality of second thermal deformation structures on the isolation layer do not overlap with each other.

13. (canceled)

14. The sensing device according to claim 1, wherein the first cavity comprises a third closed sub-cavity, and the second cavity comprises a fourth closed sub-cavity,
wherein the first electrode layer is located on a side of the third closed sub-cavity away from the isolation layer, and the second electrode layer is located on a side of the fourth closed sub-cavity away from the isolation layer.

15. The sensing device according to claim 14, wherein the first sensor further comprises a first insulating layer, a third insulating layer, a fourth insulating layer and a first supporting part, wherein the first insulating layer covers the isolation layer, the first supporting part is located between the first insulating layer and the third insulating layer and is arranged around the third closed sub-cavity, the plurality of first thermal deformation structures are in contact with the first insulating layer and the third insulating layer respectively, and the fourth insulating layer is located on a side of the first electrode layer away from the third insulating layer; and
the second sensor further comprises a fifth insulating layer, a sixth insulating layer, a seventh insulating layer and a second supporting part, wherein the isolation layer covers the fifth insulating layer, the second supporting part is located between the fifth insulating layer and the sixth insulating layer and is arranged around the fourth closed sub-cavity, the plurality of second thermal deformation structures are in contact with the fifth insulating layer and the sixth insulating layer respectively, and the second electrode layer is located between the sixth insulating layer and the seventh insulating layer.

16. The sensing device according to claim 15, wherein the first sensor further comprises a first sliding electrode, wherein the first sliding electrode is arranged in the third closed sub-cavity and overlaps with an orthographic projection of the first electrode layer on the isolation layer, and the first sliding electrode is configured to slide in a first direction, wherein the first direction is a direction perpendicular to a plane where the isolation layer is located; and
the second sensor further comprises a second sliding electrode, wherein the second sliding electrode is arranged in the fourth closed sub-cavity and overlaps with an orthographic projection of the second electrode layer on the isolation layer, and a sliding direction of the first sliding electrode and a sliding direction of the second sliding electrode are the same; or
the first sensor further comprises a third detection structure, wherein the third detection structure is arranged on a side of the first electrode layer away from the third closed sub-cavity, and an orthographic projection of the third detection structure on the isolation layer and an orthographic projection of each of the plurality of first thermal deformation structures on the isolation layer do not overlap with each other; and
the second sensor further comprises a fourth detection structure, wherein the fourth detection structure is arranged on a side of the second electrode layer away from the fourth closed sub-cavity, an orthographic projection of the fourth detection structure on the isolation layer and an orthographic projection of each of the plurality of second thermal deformation structures on the isolation layer do not overlap with each other, and the orthographic projection of the third detection structure on the isolation layer overlaps with the orthographic projection of the fourth detection structure on the isolation layer.

17. The sensing device according to claim 16, wherein an orthographic projection of the first sliding electrode on the isolation layer and an orthographic projection of each of the plurality of first thermal deformation structures on the isolation layer do not overlap with each other, and an orthographic projection of the second sliding electrode on the isolation layer and an orthographic projection of each of the plurality of second thermal deformation structures on the isolation layer do not overlap with each other; and
the first sliding electrode and the second sliding electrode each comprise a mass block and one or more extension electrodes, wherein the mass block is connected to the extension electrodes, orthographic projections of the extension electrodes on the isolation layer overlap with the orthographic projection of the first electrode layer or the second electrode layer on the isolation layer, the mass block of the first sliding electrode is slidably connected to the first supporting part, and the mass block of the second sliding electrode is slidably connected to the second supporting part.

18. The sensing device according to claim 14, wherein the second cavity further comprises a fifth open sub-cavity, wherein the fifth open sub-cavity is located on a side of the fourth closed sub-cavity away from the isolation layer;
the first sensor further comprises a first insulating layer, a third insulating layer, a fourth insulating layer and a first supporting part, wherein the first insulating layer covers the isolation layer, the first supporting part is located between the first insulating layer and the third insulating layer and is arranged around the third closed sub-cavity, the plurality of first thermal deformation structures are in contact with the first insulating layer and the third insulating layer respectively, and the fourth insulating layer is located on a side of the first electrode layer away from the third insulating layer; and
the second sensor further comprises a fifth insulating layer, a sixth insulating layer, a seventh insulating layer, a second supporting part and a third supporting part, wherein the isolation layer covers the fifth insulating layer, the second supporting part is located between the fifth insulating layer and the sixth insulating layer and is arranged around the fourth closed sub-cavity, the second electrode layer is located in the fifth open sub-cavity and is in contact with the sixth insulating layer, the third supporting part is located between the second electrode layer and the seventh insulating layer and is arranged around the fifth open sub-cavity, and the plurality of second thermal deformation structures are located in the fifth open sub-cavity and are in contact with the second electrode layer and the seventh insulating layer.

19. The sensing device according to claim 18, wherein the first sensor comprises a first sliding electrode, wherein the first sliding electrode is arranged in the third closed sub-cavity and overlaps with an orthographic projection of the first electrode layer on the isolation layer, and the first sliding electrode is configured to slide in a first direction, wherein the first direction is a direction parallel to a plane where the isolation layer is located; and
the second sensor further comprises a second sliding electrode, wherein the second sliding electrode is arranged in the fourth closed sub-cavity and overlaps with an orthographic projection of the second electrode layer on the isolation layer, and a sliding direction of the first sliding electrode and a sliding direction of the second sliding electrode are the same.

20. The sensing device according to claim 19, wherein an orthographic projection of the first sliding electrode on the isolation layer and an orthographic projection of each of the plurality of first thermal deformation structures on the isolation layer do not overlap with each other, and an orthographic projection of the second sliding electrode on the isolation layer and an orthographic projection of each of the plurality of second thermal deformation structures on the isolation layer do not overlap with each other; and
the first sliding electrode and the second sliding electrode each comprise a mass block and one or more extension electrodes, wherein the mass block is connected to the extension electrodes, orthographic projections of the extension electrodes on the isolation layer overlap with the orthographic projection of the first electrode layer or the second electrode layer on the isolation layer, the mass block of the first sliding electrode is slidably connected to the first insulating layer, the mass block of the second sliding electrode is slidably connected to the sixth insulating layer, the seventh insulating layer is provided with a plurality of first through holes, and an orthographic projection of each of the plurality of second thermal deformation structures on the isolation layer and a region surrounded by an orthographic projection of an outer contour of each of the plurality of first through holes on the isolation layer do not overlap with each other.

21. The sensing device according to claim 17, wherein the first sliding electrode and the second sliding electrode are the same;
in response to the first direction being the direction perpendicular to the plane where the isolation layer is located, a size of the mass block in the direction perpendicular to the plane where the isolation layer is located is less than a size of a cavity in which the mass block is located in the direction perpendicular to the plane where the isolation layer is located; and
in response to the first direction being the direction parallel to the plane where the isolation layer is located, sizes of the first sliding electrode and the second sliding electrode in the direction parallel to the plane where the isolation layer is located are less than sizes of cavities in which the first sliding electrode and the second sliding electrode are located in the direction parallel to the plane where the isolation layer is located.

22. (canceled)

23. (canceled)

24. (canceled)

25. (canceled)

26. (canceled)

27. (canceled)

28. (canceled)
